(19) United States
(12) Patent Application Publication
(10) Pub. No.: US 2024/0188280 A1
(43) Pub. Date: Jun. 6, 2024

(54) TWIN CHANNEL ACCESS DEVICE FOR VERTICAL THREE-DIMENSIONAL MEMORY

(71) Applicant: Micron Technology, Inc., Boise, ID (US)

(72) Inventors: Kamal M. Karda, Boise, ID (US); Si-Woo Lee, Boise, ID (US); Scott E. Sills, Boise, ID (US); Haitao Liu, Boise, ID (US)

(21) Appl. No.: 18/511,007

(22) Filed: Nov. 16, 2023

Related U.S. Application Data
(60) Provisional application No. 63/429,725, filed on Dec. 2, 2022.

(51) Int. Cl. H10B 12/00; H01L 29/06; H01L 29/08; H01L 29/423; H01L 29/66; H01L 29/775; H01L 29/786

(52) U.S. Cl. CPC H10B 12/31; H01L 29/0673; H01L 29/0847; H01L 29/42392; H01L 29/66439; H01L 29/775; H01L 29/78696; H10B 12/05; H10B 12/488

(57) ABSTRACT

Systems, methods and apparatus are provided for a twin channel access device, twin storage node memory cell in a vertical three-dimensional memory. The memory cell has a horizontally oriented access device having a first source/drain region and a second source/drain region separated by a first channel region. The first channel is actuated by a first gate separated from the first channel region by a first gate dielectric. The access device further includes a third source/drain region and a fourth source/drain region separated by a second channel region. The second channel is actuated by a second gate separated from the second channel region by a second gate dielectric. The first and the second gate are connected. A horizontally oriented storage node is coupled to the second and/or fourth source/drain regions of the twin channel access device.

### PRIORITY INFORMATION

This application claims the benefit of U.S. Provisional Application No. 63/429,725, filed on Dec. 2, 2022, the contents of which are incorporated herein by reference.

### TECHNICAL FIELD

The present disclosure relates generally to memory devices, and more particularly, to a twin channel access device for vertical three-dimensional (3D) memory.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like. Memory devices can be utilized for a wide range of electronic applications.

### BRIEF DESCRIPTION OF THE DRAWINGS

FIG. 1 is a schematic diagram illustrating a perspective view of arrays of twin channel access devices for vertical three-dimensional (3D) memory, in accordance with a number of embodiments of the present disclosure.

FIG. 2 is a perspective view of a schematic diagram illustrating an array of twin channel access devices for vertical three-dimensional (3D) memory, in accordance with a number of embodiments of the present disclosure.

FIG. 3A is a perspective view illustrating a portion of a unit cell for a twin channel access device for vertical three-dimensional (3D) memory, in accordance with a number of embodiments of the present disclosure.

FIG. 3B a perspective view illustrating an array of twin channel access devices for vertical three-dimensional (3D) memory, in accordance with a number of embodiments of the present disclosure.

FIG. 4 illustrates a view of a semiconductor structure at a particular time in the fabrication process in accordance with a number of embodiments of the present disclosure.

FIGS. 5A-5D illustrate several views of a semiconductor structure at a particular time in the fabrication process in accordance with a number of embodiments of the present disclosure.

FIGS. 6A-6E illustrate several views of a semiconductor structure at a particular time in the fabrication process in accordance with a number of embodiments of the present disclosure.

FIGS. 7A-7C illustrate several views of a semiconductor structure at a particular time in a fabrication process in accordance with a number of embodiments of the present disclosure.

FIGS. 8A-8B illustrate several views of a semiconductor structure at a particular time in a fabrication process in accordance with a number of embodiments of the present disclosure.

FIGS. 9A-9B illustrate several views of a semiconductor structure at a particular time in a fabrication process in accordance with a number of embodiments of the present disclosure.

FIGS. 10A-10B illustrate several views of a semiconductor structure at a particular time in a fabrication process in accordance with a number of embodiments of the present disclosure.

FIGS. 11A-11C illustrate several views of a semiconductor structure at a particular time in the fabrication process in accordance with a number of embodiments of the present disclosure.

FIGS. 12A-12D illustrate several views of a semiconductor structure at a particular time in the fabrication process in accordance with a number of embodiments of the present disclosure.

FIGS. 13A-13B illustrate several views of a semiconductor structure at a particular time in the fabrication process in accordance with a number of embodiments of the present disclosure.

FIG. 14 illustrates a view of a semiconductor structure at a particular time in the fabrication process in accordance with a number of embodiments of the present disclosure.

FIG. 15 is a block diagram of an apparatus in accordance with a number of embodiments of the present disclosure.

### DETAILED DESCRIPTION

Embodiments of the present disclosure describe a twin channel access devices for vertical three-dimensional (3D) memory, In one embodiment the twin channel access device includes two transistors and a shared storage node, in the form of a capacitor, forming a dynamic random access memory (DRAM) cell in a 3D memory. In some embodiments the twin channel access device includes two transistors and two storage nodes, e.g., two capacitors, forming a two transistor, two capacitor (2T2C) unit cell. The twin channel access device is horizontally oriented and coupled to horizontally oriented storage nodes within a same plane, e.g., tier, of the vertical 3D memory. The horizontally oriented transistors are integrated with horizontally oriented gates and integrated with vertically oriented digit lines. This provides good retention and scalability, in part due to less horizontal area, e.g., footprint, for the memory cells, for vertical three-dimensional memories. Additionally the twin channel access device may provide shared storage node provides for better retention relative to a same size one transistor, one capacitor (1T1C) memory cell and a better signal margin for improved sensing performance.

As DRAM scaling becomes difficult there is a quest for full 3D architectures wherein multiple levels can be formed together similar to 3D NAND. As the horizontal area, e.g., footprint, for the memory cells, for vertical three-dimensional memories decreases, a burden is placed on aspect ratios, and staircases and drivers. Further the cell storage capacitance may become more marginal. Access current on (“Ion”) needs to be boosted up as there is uncertainty on variability, particularly for larger numbers of tiers for 3D memory.

Embodiments described herein may enable two times (“twice”, or 2x) higher Ion, and may provide for 1.5× higher capacitance at a same cell volume for previous 3D vertical DRAM architecture. Alternatively, the architecture may enable 2× higher Ion with a same cell capacitance, according to a particular scale dimensions design rule, with approximately a twenty percent (20%) reduction in cell volume. For example, for a particular design rule, the cell height may include approximately a twenty-five percent (25%) cell height increase but have approximately a forty percent (40%) cell length decrease.

According to embodiments described herein, a twin channel access device for 3D memory uses two channels, effectively doubling channel width. In some embodiments, each channel is coupled to a smaller length storage node container, e.g., capacitor cell, thus having a smaller horizontal area footprint for the memory cells. This provides an approximately 2× higher Ion boost and approximately 1.2× capacitance boost with a same Mbit density. The improved performance can be harnessed in different manners including trading the 2× Ion boost for a greater than (>) 5× improved Ioff. In some embodiments Vccp can be reduced to less than (<) approximately 1.8 volts (V) which may provide significant implications for high voltage CMOS scaling and area efficiency (AE) improvement.

Further, according to embodiments, a two-channel access device, two storage node memory cell may reduce a horizontal area consumed for the vertical three-dimensional (3D) vertical memory to improve scaling and 3D vertical memory density. Additionally, the shared storage node may improve the sensing signal margin relative to a same capacitor size in a one transistor, one capacitor (1T1C) architecture. And, as an additional benefit, the arrangement of a two channel access device, two storage node memory cell relaxes the “current off” (“Ioff”) requirements, lessening current leakage in the access device “off” state while realizing equivalent charge storage retention for thin film transistor (TFT) applications.

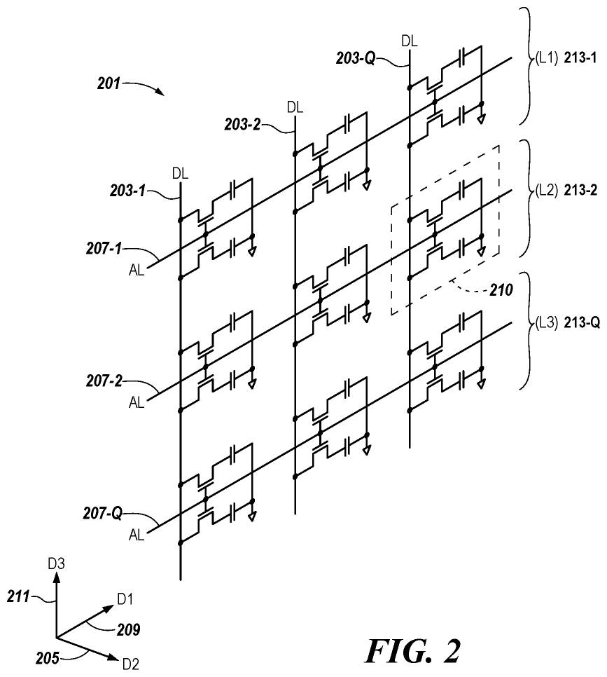

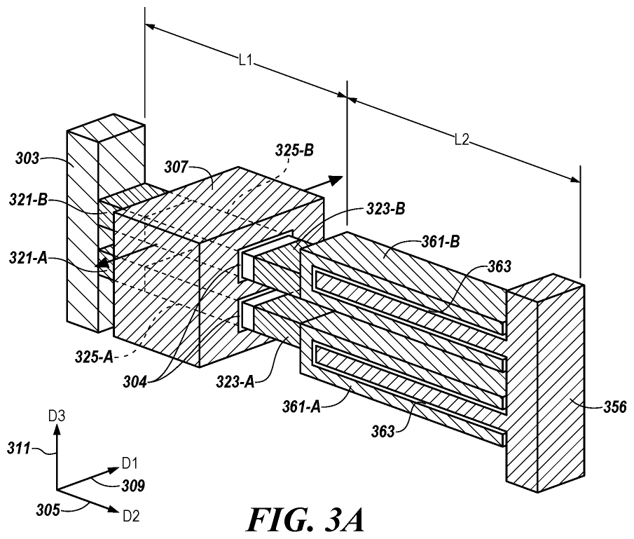

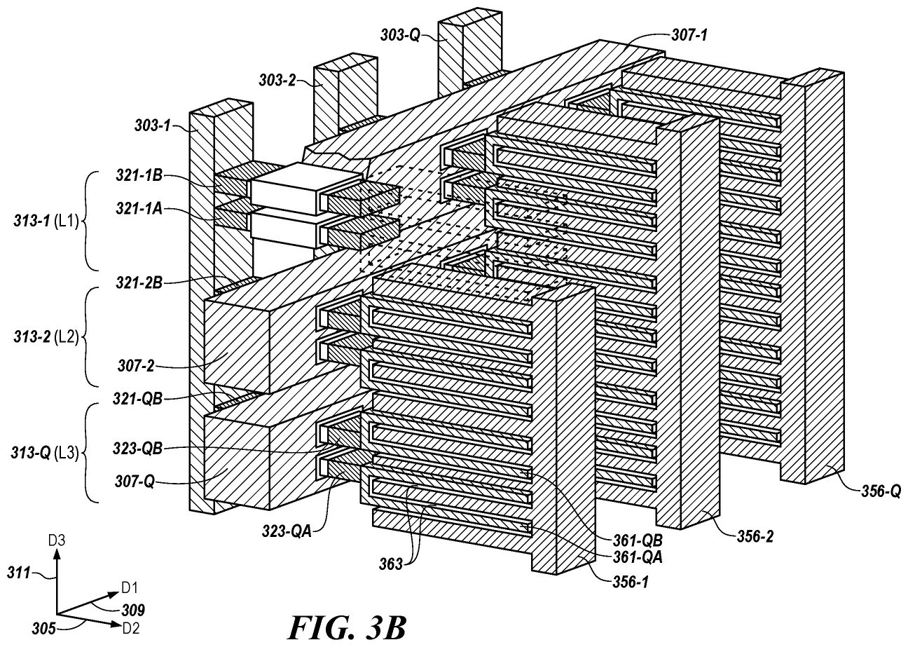

The figures herein follow a numbering convention in which the first digit or digits correspond to the figure number of the drawing and the remaining digits identify an element or component in the drawing. Similar elements or components between different figures may be identified by the use of similar digits. For example, reference numeral 223 may reference element “23” in FIG. 2, and a similar element may be referenced as 323 in FIG. 3. Multiple analogous elements within one figure may be referenced with a reference numeral followed by a hyphen and another numeral or a letter. For example, 207-1 may reference element 207-1 in FIGS. 2 and 207-2 may reference element 207-2, which may be analogous to element 207-1. Such analogous elements may be generally referenced without the hyphen and extra numeral or letter. For example, elements 207-1 and 207-2 or other analogous elements may be generally referenced as 207.

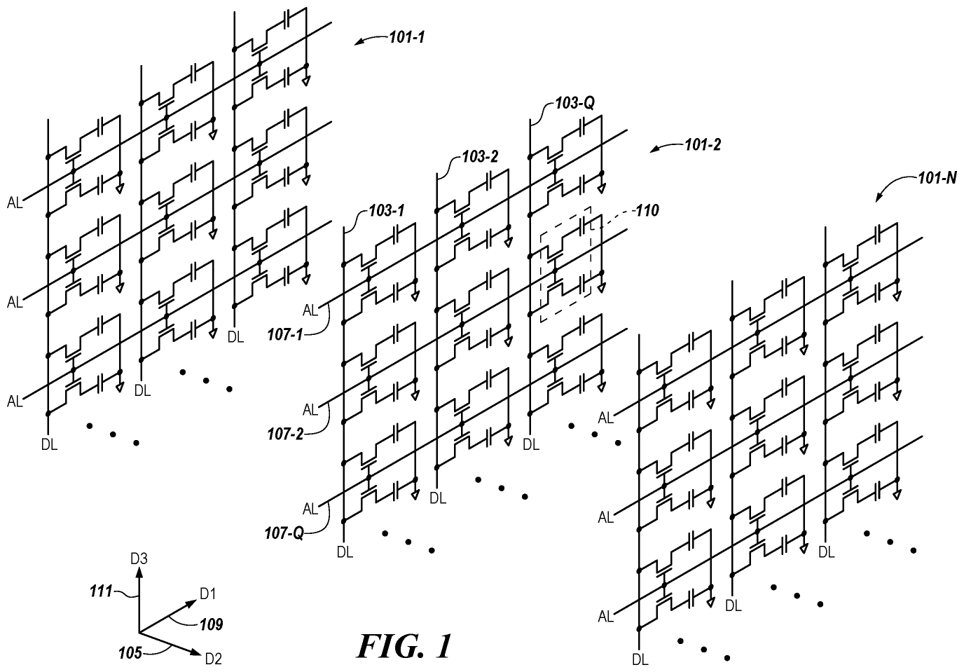

FIGS. 1 and 2 are schematic illustrations of portions of a vertical 3D memory in accordance a number of embodiments of the present disclosure. FIG. 1 illustrates a circuit diagram showing a cell array of a 3D semiconductor memory device according to an embodiment of the present disclosure having vertically oriented digit lines (e.g., vertically oriented DLs 103-1, 103-2, . . . , 103-Q) oriented in a third direction (D3) 111 and horizontally oriented gates (e.g., wordlines or access lines (AL) 107-1, 107-2, . . . , 107-Q) oriented in a first direction (D1) 109.

FIG. 1 illustrates a cell array may have a plurality of sub cell arrays 101-1, 101-2, . . . , 101-N. The sub cell arrays 101-1, 101-2, . . . , 101-N may be arranged along a second direction (D2) 105. Each of the sub cell arrays, e.g., sub cell array 101-2, may include horizontally oriented gates 107-1, 107-2, . . . , 107-Q. Each of the sub cell arrays may include vertically oriented digit lines, 103-1, 103-2, . . . , 103-Q, associated with each twin channel access device memory cell. According to embodiments, the first direction (D1) 109 and the second direction (D2) 105 may be considered in a horizontal (“X-Y”) plane. The third direction (D3) 111 may be considered in a vertical (“Z”) plane. Hence, according to embodiments described herein, the horizontally oriented gates 107-1, 107-2, . . . , 107-Q (e.g., wordlines (or access lines (AL), are extending in a horizontal direction, e.g., first direction (D1) 109.

A memory cell (e.g., 110) may include two transistors 115-A and 115-B, and a shared capacitor or pair of capacitors 101, oriented in the second direction (D2) 105 located at intersections of the horizontally oriented gates 107-1, 107-2, . . . , 107-Q (e.g., wordlines (WL)) oriented in the first direction (D1) 109, and the vertically oriented digit lines, 103-1, 103-2, . . . , 103-Q, oriented in the third direction (D3) 111. Memory cells may be written to, or read from, using the horizontally oriented gates 107-1, 107-2, . . . , 107-Q, and the vertically oriented digit lines, 103-1, 103-2, . . . , 103-Q.

FIG. 2 illustrates a circuit diagram showing a cell array of a 3D semiconductor memory device according to an embodiment of the present disclosure having vertically oriented digit lines (DL), 203-1, 203-2, . . . , 203-Q, oriented in the third direction (D3) 211 and horizontally oriented gates (e.g., horizontally oriented WLs) 207-1, 207-2, . . . , 207-Q oriented in the first direction (D1) 209. FIG. 2 is a perspective view showing a portion of a sub cell array 101-2 shown in FIG. 1 as a vertically oriented stack of memory cells in an array, according to some embodiments of the present disclosure.

As shown in the example embodiment of FIG. 2, the array of vertically oriented memory cells may be extending in a vertical direction, e.g., third direction (D3) 211. According to some embodiments the vertically oriented stack of memory cells may be fabricated such that the memory cells are formed on plurality of vertical levels (e.g., a first level 213-1 (L1), a second level 213-2 (L2), and a third level 213-Q (L3)).

FIGS. 3A-3B are a perspective views illustrating a portion of a semiconductor device in accordance with a number of embodiments of the present disclosure. FIG. 3A illustrates an example embodiment of a twin channel access device unit cell having a horizontally oriented access device coupled to a horizontally oriented storage node. In the example embodiment shown in FIG. 3A each respective channel is coupled separately to a respective storage node within the unit cell. In this embodiment, the unit memory cell is formed as a two transistor, two capacitor (2T2C) memory cell (e.g., 110 in FIG. 1) within the vertically stacked array of memory cells (e.g., within a sub cell array 101-2 in FIG. 1). FIG. 3B illustrates an embodiment of the multiple unit cells, in multiple tiers, within a three-dimensional (3D) memory array.

In the example embodiment of FIG. 3A, the unit cell includes a first source/drain region 321-A and a second source/drain region 323-A separated by a first channel region 325-A. The first channel region 325-A is controlled by a gate 307, separated from the first channel region 325-A by a gate dielectric 304. As further shown in the example embodiment of FIG. 3A, the unit cell includes a third source/drain region 321-B separated from a fourth source/drain region 323-B by a second channel region 325-B. The second channel region 325-B of the twin channel access device may also be controlled by the gate 307, separated from the second channel region 325-B by the gate dielectric 304. According to embodiments, the gate 307 is a horizontally oriented gate shown extending in the first direction (D1) 309. The first, second, third, and fourth source/drain regions 321-A, 323-A, 321-B, and 323-B may be impurity doped regions and may be formed from an n-type or p-type dopant. Embodiments are not so limited.

For example, for an n-type conductivity transistor construction the body region and/or twin channels 325-A and 325-B of the access device may be formed of a low doped (p-) p-type semiconductor material. In one embodiment, the twin channels 325-A and 325-B of the access device, respectively separating the first, second, third, and fourth source/drain regions 321-A, 323-A, 321-B, and 323-B, may include a low doped, p-type (e.g., low dopant concentration (p-)) polysilicon material consisting of boron (B) atoms as an impurity dopant to the semiconductor material (e.g., polycrystalline silicon, among others). The twin channels 325-A and 325-B of the access device may also comprise a metal, and/or metal composite materials containing ruthenium (Ru), molybdenum (Mo), nickel (Ni), titanium (Ti), copper (Cu), a highly doped degenerate semiconductor material, and/or at least one of indium oxide (In₂O₃), or indium tin oxide (In₂₋ₓSnₓO₃), formed using an atomic layer deposition process, etc. Embodiments, however, are not limited to these examples. As used herein, a degenerate semiconductor material is intended to mean a semiconductor material, such as polysilicon, containing a high level of doping with significant interaction between dopants, e.g., phosphorous (P), boron (B), etc. Non-degenerate semiconductors, by contrast, contain moderate levels of doping, where the dopant atoms are well separated from each other in the semiconductor host lattice with negligible interaction.

In some embodiments the twin channels 325-A and 325-B may include silicon, germanium, silicon-germanium, and/or indium gallium zinc oxide (IGZO). The gate dielectric material 304 may include, for example, a high-k dielectric material, a silicon oxide material, a silicon nitride material, a silicon oxynitride material, etc., or a combination thereof. Embodiments are not so limited. For example, in high-k dielectric material examples the gate dielectric material 304 may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobite, etc.

For the n-type conductivity transistor construction, the first, second, third, and fourth source/drain regions 321-A, 323-A, 321-B, and 323-B may include a high dopant concentration, n-type conductivity impurity (e.g., high dopant (n+) or (n++)) doped in the source/drain regions. In some embodiments, the high dopant, n-type conductivity first, second, third, and fourth source/drain regions 321-A, 323-A, 321-B, and 323-B may include a high concentration of Phosphorus (P) atoms deposited therein. Embodiments, however, are not limited to this example. In other embodiments, the twin channels 325-A and 325-B of the access device may be of a n-type conductivity construction in which case the impurity, e.g., dopant, conductivity types would be reversed.

As shown in the example embodiment of FIG. 3A, the twin channels 325-A and 325-B of the access device are coupled separately to a respective storage node within the unit cell. Embodiments, however, are not so limited and in other embodiments the twin channels 325-A and 325-B of the access device may share a common storage node. As shown in the example embodiment of FIG. 3A, a first electrode, e.g., bottom electrode (BE), 361-A of a first horizontally oriented storage node is coupled to the second source/drain region 323-A of the twin channel access device. A first electrode, e.g., bottom electrode (BE), 361-B of a second horizontally oriented storage node is coupled to the fourth source/drain region 323-B of the twin channel access device. As shown in the embodiment of FIG. 3A a cell dielectric 363 separates the first electrodes 361-A and 361-B from a second electrode, e.g., top electrode (TE), 356. As shown in the embodiment of FIG. 3A the second electrode 356 may be a common electrode 356. Further, as shown in the embodiment of FIG. 3A, the first source/drain region 321-A and the third source/drain region 321-A of the twin channel access device are coupled to a vertically oriented digit line 303.

Hence, in the example embodiment shown in FIG. 3A, the first and the second channels 325-A and 325-B of the twin channel access device are formed in a dual gate structure having a top gate portion vertically above the first channel 325-A and a bottom gate portion vertically below the first channel 325-A. Similarly the dual gate structure includes a top gate portion vertically above the second channel 325-B and a bottom gate portion vertically below the second channel 325-B. In this embodiment the top gate portion of the first channel 325-A is shared as the bottom gate portion of the second channel 325-B as a shared gate portion between the first channel 325-A. In this manner, the twin channel 325-A and 325-B access device may be referenced as having a first horizontal gate portion, a second horizontal gate portion, and a third horizontal gate portion. The first, second, and third horizontal gate portions are electrically coupled together to form gate on two side (G2S) structures and/or gate all around (GAA) structures on opposing sides, respectively, of the first and the second horizontal channel regions 325-A and 325-B.

Since the second horizontal gate is shared as a top portion to the first channel 325-A and a bottom portion to the second channel 325, in some embodiments, the second horizontal gate has a vertical height (h2) which is less than a vertically height (h1) of the first horizontal gate and is less than a vertical height (h3) of the third horizontal gate. When actuated the second horizontal gate portion inverts a conductive path in both opposing sides of the first and the second horizontal channel regions 325-A and 325-B to double a width of the conductive path in the first and the second horizontal channel regions 325-A and 325-B.

As shown in the embodiment of FIG. 3A, the first and the second channel regions 325-A and 325-B have a first horizontal length (L1) and the first and the second horizontal storage nodes have a second horizontal length (L2). According to some embodiments, the second horizontal length (L2) is at least twenty five percent (25%) shorter than a storage node length used to maintain an equal storage capacitance value relative to a same horizontal memory device layout architecture having only a single channel horizontal access device, using a same set of operating parameters. Further, the first and the second channel regions 325-A and 325-B may have a cumulative channel width doubling a current on (“Ion”) value relative to a same horizontal memory device layout architecture having only a single channel horizontal access device, using a same set of operating parameters. In some embodiments, a power supply operating voltage (“Vccp”) to the twin channel access device for a memory device is less than 2.0 volts. In some embodiments, the twin channel horizontally oriented access device forms first and a second horizontally oriented, thin film transistors (TFTs) and the first and the second horizontally oriented storage nodes are horizontally oriented capacitors located in a same horizontal tier to form a twin transistor, twin capacitor (2T2C) memory cell. Embodiments, however, are not so limited, and in some embodiments the first and the second horizontally oriented storage nodes are horizontally oriented, ferroelectric storage nodes.

FIG. 3B is a perspective view illustrating an array of vertical, twin channel memory cells for 3D memory according to embodiments of the present disclosure. As shown in FIG. 3B, an array of vertically stacked, horizontally oriented twin channel access device, twin storage node memory cells may be provided in a vertically oriented three-dimensional (3D), multi-level (e.g., multi-tiered) 313-1, 313-2, . . . , 313-N memory array with each tier 313-1, 313-2, . . . , 313-N having twin channel, horizontally oriented access devices and first and second horizontally oriented storage nodes. As described in FIG. 3A, the memory cells each include a first source/drain region 321-1A, 321-2A, . . . , 321-QA and a second source/drain region 323-1A, 323-2A, . . . , 323-QA separated by a first channel region 325-1A, 325-2A, . . . , 325-QA, being operatively controlled by horizontal gates 307-1, 307-2, . . . , 307-Q along rows, within tiers 313-1 (L1), 313-2 (L2), . . . , 313-Q (L3), of vertically oriented memory cells, and extending in a first direction (D1) 309. The horizontal gates 307-1, 307-2, . . . , 307-Q are separated from the first channel region 325-1A, 325-2A, . . . , 325-QA by gate dielectrics 304-1, 304-2, . . . , 304-Q. Third source/drain regions 321-1B, 321-2B, . . . , 321-QB and fourth source/drain regions 323-1B, 323-2B, 323-QB are separated by a second channel region 325-1B, 325-2B, . . . , 325-QB, being operatively controlled by the horizontal gates 307-1, 307-2, . . . , 307-Q and separated from the second channel regions 325-1B, 325-2B, . . . , 325-QB by the gate dielectrics 304-1, 304-2, . . . , 304-Q.

As shown in the embodiment of FIG. 3B, first electrodes 361-1A, 361-2A, 361-QA of first horizontally oriented storage nodes are coupled to the second source/drain region 323-1A, 323-2A, . . . , 323-QA of the first horizontally oriented channels 325-1A, 325-2A, . . . , 325-QA. Further, first electrodes 361-1B, 361-2B, . . . , 361-QB of second horizontally oriented storage nodes are coupled to the fourth source/drain regions 323-1B, 323-2B, . . . , 323-QB of the second horizontal channels 325-1B, 325-2B, . . . , 325-Q. Cell dielectrics 363 separate the first electrodes 361-1A, 361-2A, 361-QA and 361-1B, 361-2B, . . . , 361-QB from a second electrode 356-1, 356-2, . . . , 356-Q (e.g., top electrode (TE)) which may be a common electrode (CE) to a column of vertically oriented memory cells in the third direction (D3) 311. Vertical digit lines 303-1, 303-2, . . . , 303-Q are coupled to the first source/drain regions 321-1A, 321-2A, . . . , 321-QA of the first horizontal channels 325-1A, 325-2A, . . . , 325-QA and to the third source/drain regions 321-1B, 321-2B, . . . , 321-QB of the second horizontal channels in columns of the vertically oriented memory cells in the third direction (D3) 311.

As described in FIG. 3A, the gate structures 307-1, 307-2, . . . , 307-Q, along rows within tiers 313-1 (L1), 313-2 (L2), . . . , 313-Q (L3), of vertically oriented memory cells and extending in a first direction (D1) 309 may be electrically coupled together and form gate all around (GAA) structures opposing the first and the second horizontal channels 325-1A, 325-2A, . . . , 325-QA, and 325-1B, 325-2B, . . . , 325-Q along rows within each tier 313-1 (L1), 313-2 (L2), . . . 313-Q (L3). When actuated the GAA structures invert a conductive path in opposing sides of the first and the second horizontal channels 325-1A, 325-2A, . . . , 325-QA, and 325-1B, 325-2B, . . . , 325-Q to double a width of the conductive path in the first and the second horizontal channels 325-1A, 325-2A, . . . , 325-QA, and 325-1B, 325-2B, . . . , 325-Q.

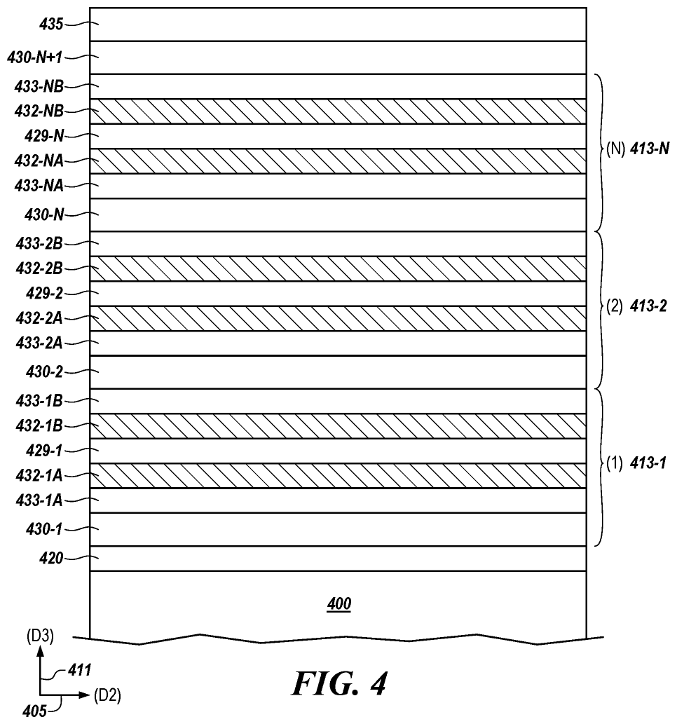

As described further in connection with FIGS. 4-12, embodiments for a twin channel access device described herein may have a total vertical height (ht) of less than one hundred and fifty (150) nanometers (nm). A second horizontal gate, e.g., middle gate, between the first and the second horizontal channels 325-1A, 325-2A, . . . , 325-QA, and 325-1B, 325-2B, . . . , 325-Q may have a vertical height (h2) of less than ten (10) nanometers (nm). And the first and the second horizontal channels 325-1A, 325-2A, . . . , 325-QA, and 325-1B, 325-2B, . . . , 325-Q may each individually have a vertical height (hc1/hc2) of less than fifteen (15) nanometers (nm). In some embodiments, the first and the second horizontally oriented storage nodes each have a horizontal length (L2) of less than three hundred (300) nanometers (nm). And in some embodiments, the first and the second horizontally oriented storage nodes each have a horizontal length (L2) of less than two hundred (200) nanometers (nm). Embodiments, however, are not limited to these examples, and other design rule dimensions are included within the scope of embodiments.

FIG. 4 is a cross-sectional view for an example embodiment of a semiconductor device fabrication process for a twin channel access device for memory cells in vertical 3D memory in accordance with a number of embodiments of the present disclosure. In the embodiment shown in FIG. 4, a semiconductor device fabrication process comprises depositing alternating layers of a first dielectric material, 430-1, 430-2, . . . , 430-N (collectively referred to as “first” dielectric material “430”), a second dielectric material, 433-1A, 433-2A, . . . , 433-NA, a first semiconductor material, 432-1A, 432-2A, . . . , 432-NA, a third dielectric material, 429-1, 429-2, . . . , 429-N (third dielectric material, sometimes referred to herein collectively as third dielectric material “429”), a second semiconductor material, 432-1B, 432-2B, . . . , 432-NB (first and second semiconductor material, sometimes collectively referred to herein as “semiconductor material 432”), and a fourth dielectric material, 433-1B, 433-2B, . . . , 433-NB (second and fourth dielectric material, sometimes collectively referred to herein as “second dielectric material 433”), in repeating iterations to form a vertical stack 416 on a working surface of a substrate 400. The alternating materials in the repeating, vertical stack 416 may be separated from the substrate 400 by an insulator material 420. In one embodiment, the first dielectric material 430 can be deposited to have a thickness, e.g., vertical height in the third direction (D3), in a range of twenty (20) nanometers (nm) to sixty (60) nm. In one embodiment, the semiconductor material 432 can be deposited to have a thickness, e.g., vertical height, in a range of twenty (20) nm to one hundred (100) nm. In one embodiment, the second dielectric material 433 can be deposited to have a thickness, e.g., vertical height, in a range of ten (10) nm to thirty (30) nm. In one embodiment, the third dielectric material 429 can be deposited to have a thickness, e.g., vertical height, in a range of five (5) nm to twenty (20) nm. Embodiments, however, are not limited to these examples. As shown in FIG. 4, a vertical direction 411 is illustrated as a third direction (D3), e.g., z-direction in an x-y-z coordinate system.

In some embodiments, the first dielectric material, 430-1, 430-2, . . . , 430-N, may be an interlayer dielectric (ILD). By way of example, and not by way of limitation, the first dielectric material, 430-1, 430-2, . . . , 430-N, may comprise an oxide material, e.g., SiO₂. In another example the first dielectric material, 430-1, 430-2, . . . , 430-N, may comprise a silicon nitride (Si₃N₄) material (also referred to herein as “SiN”). In another example the first dielectric material, 430-1, 430-2, . . . , 430-N, may comprise a silicon oxy-carbide (SiOₓC_{y}) material. In another example the first dielectric material, 430-1, 430-2, . . . , 430-N, may include silicon oxy-nitride (SiOₓN_{y}) material (also referred to herein as “SiON”), and/or combinations thereof. Embodiments are not limited to these examples. According to embodiments, the first dielectric material 430 may be etched selective to the second and third dielectric materials 433 and 429.

In some embodiments the semiconductor material, 432-1, 432-2, . . . , 432-N, may comprise a silicon (Si) material in a polycrystalline and/or amorphous state. The semiconductor material 432 may be a low doped, p-type (p-) silicon material. The semiconductor material 432 may be formed by gas phase doping boron atoms (B), as an impurity dopant, at a low concentration to form the low doped, p-type (p-) silicon material. The low doped, p-type (p-) silicon material may be a polysilicon material. Embodiments, however, are not limited to these examples.

In some embodiments, the second dielectric material 433 may comprise a nitride material. The nitride material may be a silicon nitride (Si₃N₄) material (also referred to herein as “SiN”). In another example the second dielectric material 433 may comprise a silicon oxy-carbide (SiOC) material. In another example the second dielectric material 433 may include silicon oxy-nitride (SiON), and/or combinations thereof. Embodiments are not limited to these examples. However, according to embodiments, the second dielectric material 433 is purposefully chosen to be different in material or composition than the first dielectric material 430 and third dielectric material 429, such that a selective etch process may be performed on one of the first, second, and third dielectric layers, selective to the other ones of the first, second, and third dielectric layers, e.g., the second dielectric material 433 may be selectively etched relative to the semiconductor material 432, the first dielectric material 430, and the third dielectric material 429.

The repeating iterations of alternating first dielectric material, 430-1, 430-2, . . . , 430-N, the second dielectric material, 433-1A, 433-2A, . . . , 433-NA, the first semiconductor material, 432-1A, 432-2A, . . . , 432-NA, the third dielectric material, 429-1, 429-2, . . . , 429-N, the second semiconductor material, 432-1B, 432-2B, . . . , 432-NB, and the fourth dielectric material, 433-1B, 433-2B, . . . , 433-NB layers may be deposited according to a semiconductor fabrication process such as chemical vapor deposition (CVD) in a semiconductor fabrication apparatus. Embodiments, however, are not limited to this example and other suitable semiconductor fabrication techniques may be used to deposit the alternating layers of the first dielectric material 430, the second dielectric material 433-A, the first ≥semiconductor material 432-A, the third dielectric material 429, the second semiconductor material 432-B, and the fourth dielectric material 433-B, in repeating iterations to form the vertical stack 416.

The layers may occur in repeating iterations vertically. In the example of FIG. 4, three tiers, numbered 1, 2, and N, 413-1, 413-2, . . . , 413-N, of the repeating iterations 1-N are shown. Embodiments, however, are not limited to the number of tiers “N”. For example, in some embodiments fifty (50) or more tiers (N≥50) may be included. Embodiments, however, are not limited to this example and more or fewer repeating iterations may be included.

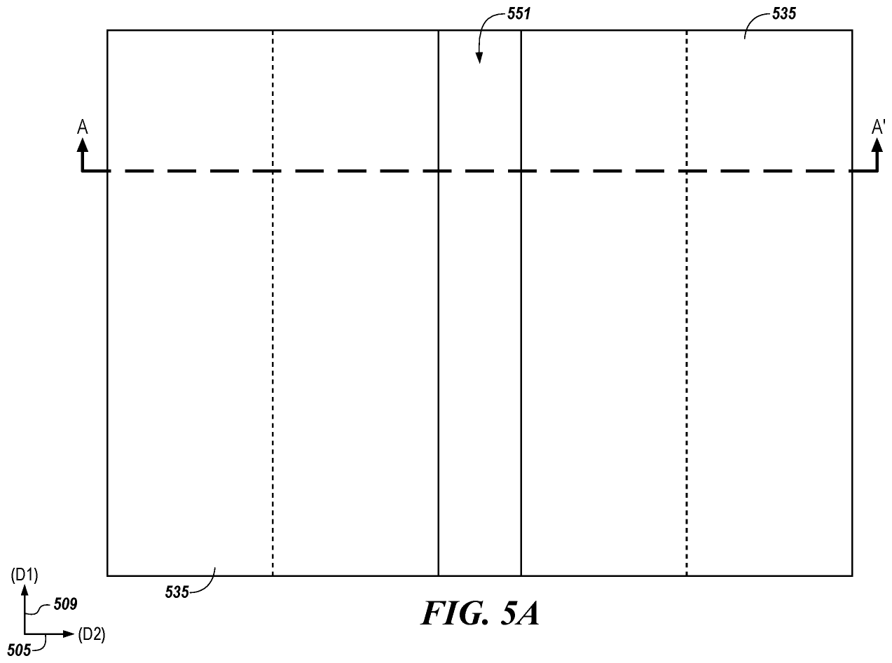

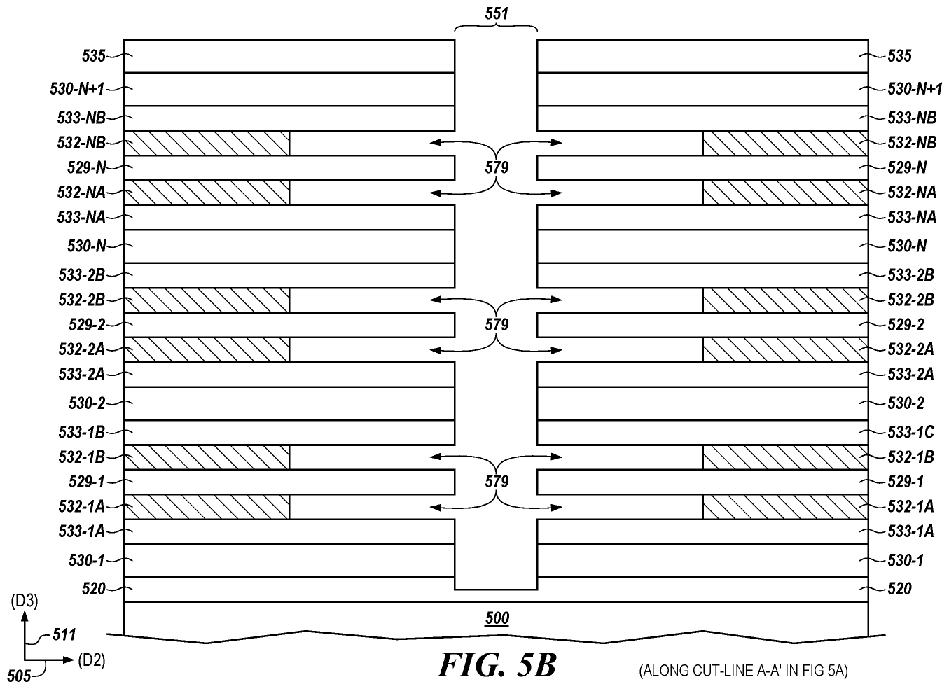

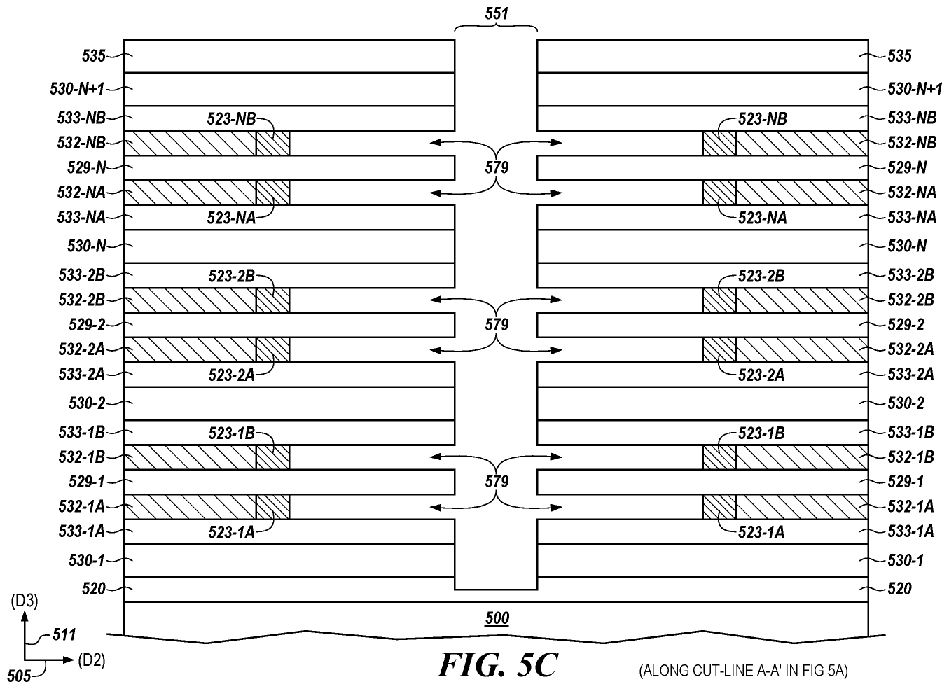

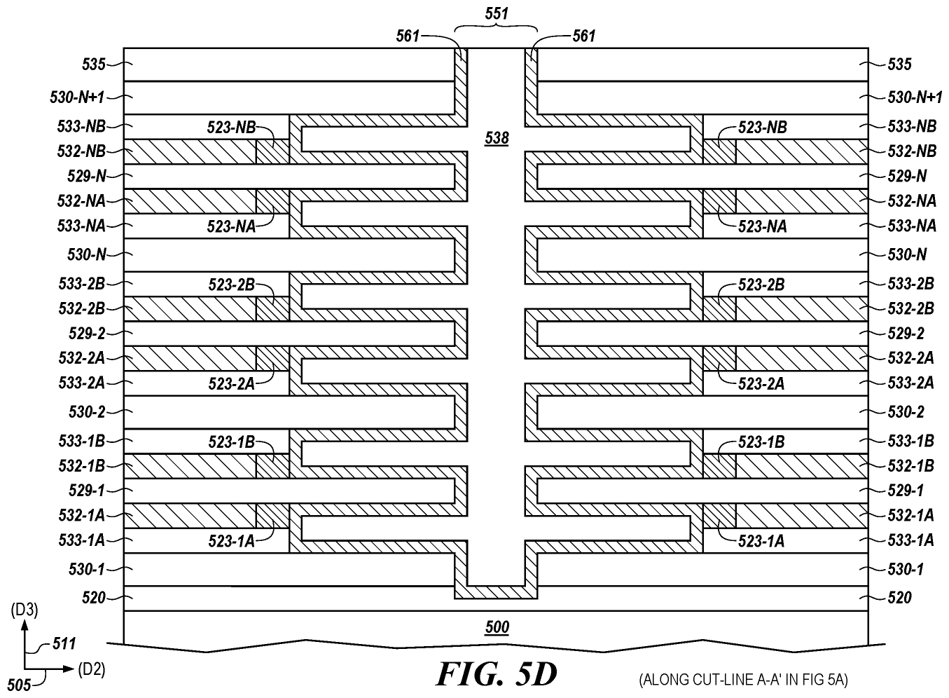

FIGS. 5A-5D illustrate a view of a semiconductor device in fabrication, at another stage of a semiconductor device fabrication process in accordance with a number of embodiments of the present disclosure.

FIG. 5A illustrates a top down view example method, at another stage of a semiconductor fabrication process, for forming arrays of vertically stacked memory cells, having twin channel access device for vertical three-dimensional (3D) memory. In one embodiment, the arrays include two access devices and two storage nodes per unit cell formed with horizontally oriented access devices, horizontally oriented storage nodes, and horizontally oriented access lines, such as illustrated in FIGS. 1-3, and in accordance with a number of embodiments of the present disclosure. In the example embodiment of FIG. 5A, the method comprises using a photolithographic process to pattern the photolithographic mask 535. The method in FIG. 5A further illustrates using one or more etchant processes to form a vertical opening 551 in a storage node region through the vertical stack and extending predominantly in the first horizontal direction (D1) 509. The one or more etchant processes forms a vertical opening 551 to expose sidewalls in the repeating iterations of alternating layers of a first dielectric material, 530-1, 530-2, . . . , 530-N, a second dielectric material, 533-1A, 533-2A, . . . , 533-NA, a first semiconductor material, 532-1A, 532-2A, . . . , 532-NA, a third dielectric material, 529-1, 529-2, . . . , 529-N, a second semiconductor material, 532-1B, 532-2B, . . . , 532-NB, and a fourth dielectric material, 533-1B, 533-2B, . . . , 533-NB, in the vertical stack, shown in FIGS. 5B-5D, adjacent a storage node region of the semiconductor material.

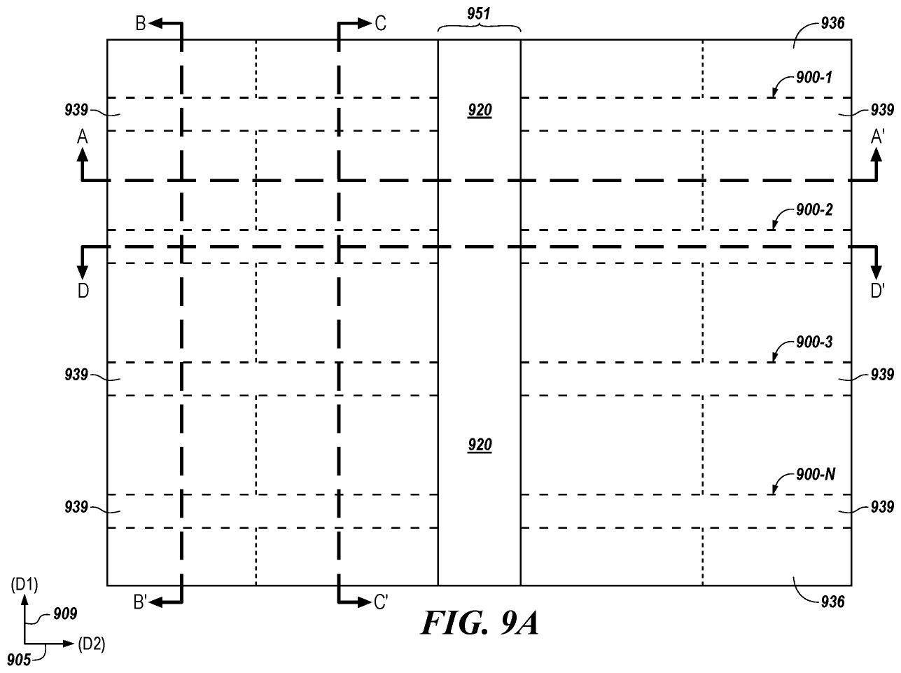

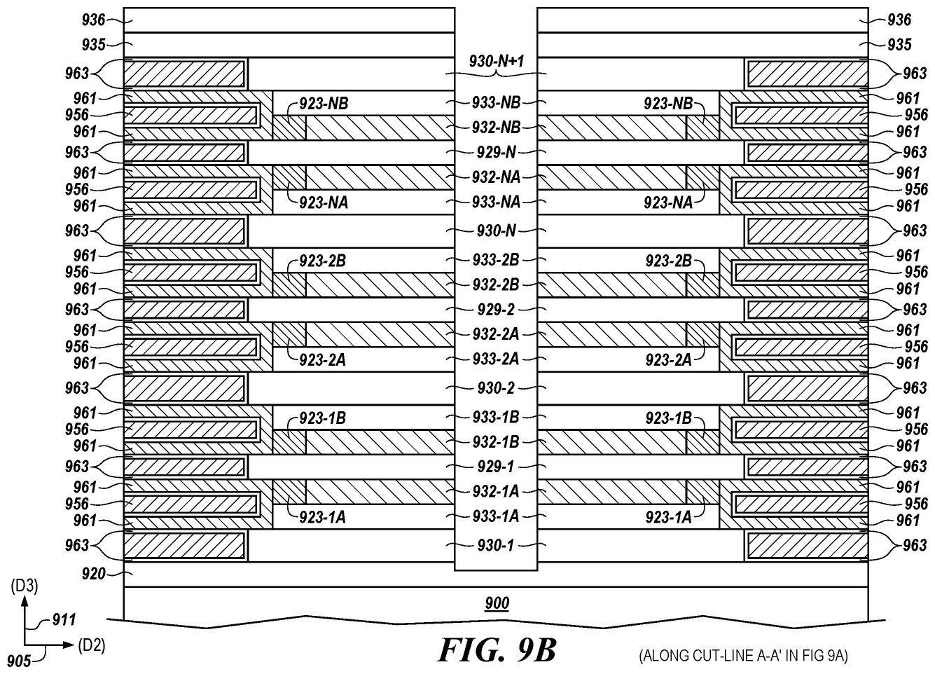

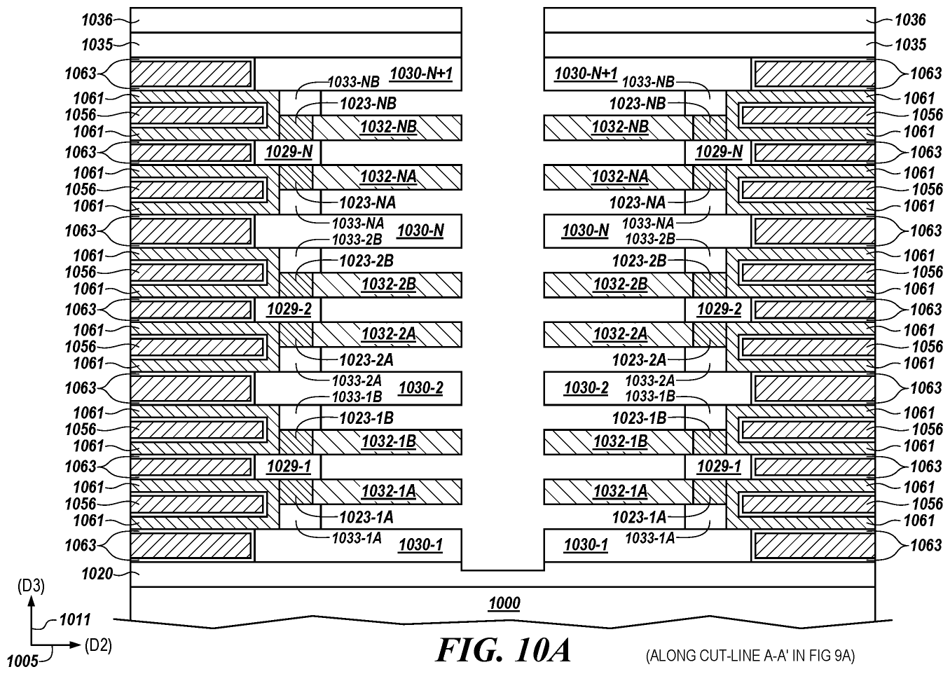

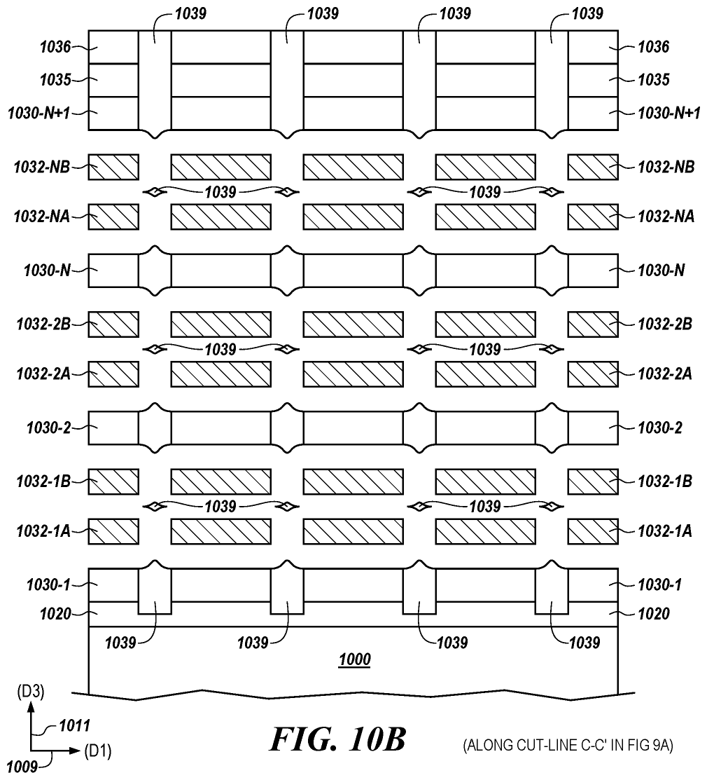

In some embodiments, this process may be performed after the access device semiconductor fabrication process described in connection with FIGS. 9-12. However, the embodiment shown in FIGS. 5B-5D illustrate a sequence in which the storage node fabrication process is performed “before” access device formation.

FIG. 5B illustrates a cross sectional view, taken along cut-line A-A′ in FIG. 5A, showing another view of the semiconductor structure at this point in one example semiconductor fabrication process of an embodiment of the present disclosure. According to this example embodiment, shown in FIG. 5B, the method comprises forming the first vertical opening 551 in the vertical stack (shown in FIG. 4) and selectively etching the first semiconductor material, 532-1A, 532-2A, . . . , 532-NA and the second semiconductor material, 532-1B, 532-2B, . . . , 532-NB in the storage node region to form first horizontal openings 579 a first horizontal distance (L1) back from the vertical opening 551 in the vertical stack (FIG. 4). According to embodiments, selectively etching the storage node region of the first semiconductor material, 532-1A, 532-2A, 532-NA and the second semiconductor material, 532-1B, 532-2B, . . . , 532-NB can comprise using an atomic layer etching (ALE) process. Embodiments, however, are not limited to this example.

FIG. 5C illustrates a cross sectional view, taken along cut-line A-A′ in FIG. 5A, showing another view of the semiconductor structure at another point in one example semiconductor fabrication process of an embodiment of the present disclosure. As shown in the example embodiment of FIG. 5C, source/drain regions 523-1A and 523-1B, 523-2A and 523-2B, . . . 523-NA and 523-NB (e.g., second and fourth source/drain regions) can be formed in the first semiconductor material, 532-1A, 532-2A, . . . , 532-NA and the second semiconductor material, 532-1B, 532-2B, . . . , 532-NB at a distal end of the first horizontal openings 579 from the vertical opening 551.

The source/drain regions 523-1A and 523-1B, 523-2A and 523-2B, . . . , 523-NA and 523-NB may be formed by gas phase doping a dopant into an edge surface portion of the semiconductor material 532. In some embodiments, the source/drain regions 523-1A and 523-1B, 523-2A and 523-2B, . . . , 523-NA and 523-NB may be adjacent a channel region. In one example, gas phase doping may be used to achieve a highly isotropic e.g., non-directional doping, to form the second and the fourth source/drain regions 523-1A and 523-1B, 523-2A and 523-2B, . . . 523-NA and 523-NB to horizontally oriented access device regions. In another example, thermal annealing with doping gas, such as phosphorous may be used with a high energy plasma assist to break the bonding. Embodiments, however, are not so limited and other suitable semiconductor fabrication techniques may be utilized.

According to one example embodiment, as shown in FIG. 5C the second and the fourth source/drain regions 523-1A and 523-1B, 523-2A and 523-2B, . . . 523-NA and 523-NB may be formed by flowing a high energy gas phase dopant, such as Phosphorous (P) for an n-type transistor, into the vertical and horizontal openings 551 and 579 to dope the dopant in the first semiconductor material, 532-1A, 532-2A, . . . , 532-NA and the second semiconductor material, 532-1B, 532-2B, . . . , 532-NB at a distal end of the first horizontal openings 579 from the vertical opening 551.

As shown in FIG. 5C, a vertical direction 511 is illustrated as a third direction (D3), e.g., z-direction in an x-y-z coordinate system, analogous to the third direction (D3) 111, among first, second, and third directions, shown in FIGS. 1-3. The plane of the drawing sheet, extending right and left, is in a second direction (D2) 505 along an axis of orientation of the horizontal access devices and horizontal storage nodes of the arrays of vertically stacked memory cells of the three-dimensional (3D) memory. In the example embodiment of FIG. 5C, the materials within the vertical stack, e.g., the repeating iterations of alternating layers of a first dielectric material, 530-1, 530-2, . . . , 530-N, a second dielectric material, 533-1A, 533-2A, . . . , 533-NA, a first semiconductor material, 532-1A, 532-2A, 532-NA, a third dielectric material, 529-1, 529-2, . . . , 529-N, a second semiconductor material, 532-1B, 532-2B, . . . , 532-NB, and a fourth dielectric material, 533-1B, 533-2B, . . . , 533-NB, are extending into and out of the plane of the drawing sheet in first direction (D1).

FIG. 5D illustrates a cross sectional view, taken along cut-line A-A′ in FIG. 5A, showing another view of the semiconductor structure at this point in one example semiconductor fabrication process of an embodiment of the present disclosure. The cross sectional view shown in FIG. 5D is illustrated extending in the second horizontal direction (D2) 505, left and right along the plane of the drawing sheet, along repeating iterations of alternating layers of a first dielectric material, 530-1, 530-2, . . . , 530-N, a second dielectric material, 533-1A, 533-2A, . . . , 533-NA, a first semiconductor material, 532-1A, 532-2A, . . . , 532-NA, a third dielectric material, 529-1, 529-2, . . . , 529-N, a second semiconductor material, 532-1B, 532-2B, . . . , 532-NB, and a fourth dielectric material, 533-1B, 533-2B, . . . , 533-NB, in the vertical stack which are extending into and out of the plane of the drawing sheet in first direction (D1), and in which the horizontally oriented access devices and horizontally oriented storage nodes, e.g., capacitor cells, can be formed within the layers the first semiconductor material, 532-1A, 532-2A, . . . , 532-NA, and the second semiconductor material, 532-1B, 532-2B, . . . , 532-NB.

In the example embodiment of FIG. 5D, a vertical opening 551 and horizontal openings 579 are shown formed from the mask, patterning, and etching process described in connection with FIG. 5B. As shown in FIG. 5D, the first semiconductor material, 532-1A, 532-2A, 532-NA, and the second semiconductor material, 532-1B, 532-2B, . . . , 532-NB in the storage node region has been selectively removed to form the horizontal openings 579.

As further shown in the embodiment of FIG. 5D, the second dielectric material, 533-1A, 533-2A, . . . , 533-NA and the fourth dielectric material, 533-1B, 533-2B, . . . , 533-NB may be selectively removed the first horizontal distance (L1) from the first vertical opening 551 to enlarge the first horizontal openings 579. In one example, the second dielectric material, 533-1A, 533-2A, . . . , 533-NA and the fourth dielectric material, 533-1B, 533-2B, . . . , 533-NB may be selectively removed the first horizontal distance (L1) from the first vertical opening 551 using an atomic layer etching (ALE) process to selectively etch the second dielectric material, 533-1A, 533-2A, . . . , 533-NA and the fourth dielectric material, 533-1B, 533-2B, . . . , 533-NB the first horizontal distance (L1) from the first vertical opening 551.

As shown in the embodiment of FIG. 5D, a first electrode 561, e.g., bottom electrode, may then be deposited in the first vertical opening 551 and the first horizontal openings in direct electrical contact with the source/drain regions 523-1A and 523-1B, 523-2A and 523-2B, 523-NA and 523-NB (e.g., second and fourth source/drain regions) formed in the first semiconductor material, 532-1A, 532-2A, . . . , 532-NA and the second semiconductor material, 532-1B, 532-2B, . . . , 532-NB at a distal end of the first horizontal openings 579. In one example embodiment, the first electrode 561 may be conformally deposited using atomic layer deposition (ALD). Embodiments, however, are not limited to this example.

To note, source/drain region references may be enumerated herein to denote two separate and distinct source/drain regions, it is not intended that the source/drain region referred to as the “first”, “second”, “third”, and/or “fourth” source/drain regions have some unique meaning. It is intended only to illustrate that source/drain regions on one side of a channel region may be connected to a digit line, e.g., 107-2, and the other source/drain regions on another side of a channel may be connected to a storage node.

FIG. 5D further illustrates filling the first vertical opening 551 and the first horizontal openings 579 with a fifth dielectric 538. In one example embodiment, the fifth dielectric material 538 may be an oxide or other suitable spin on dielectric (SOD). In some embodiments, the fifth dielectric material 538 may be a same type dielectric material as used for the first dielectric material 530. Embodiments, however, are not so limited. In another embodiment, the fifth dielectric material 538 may comprise a nitride material. In another embodiment, fifth dielectric material 538 may comprise a silicon nitride (Si₃N₄) material (also referred to herein as “SiN”). In another embodiment the fifth dielectric material 538 may include silicon dioxide (SiO₂) material. In another embodiment the fifth dielectric material 538 may comprise a silicon oxy-carbide (SiOₓC_{y}) material, and/or combinations thereof. Embodiments are not limited to these examples.

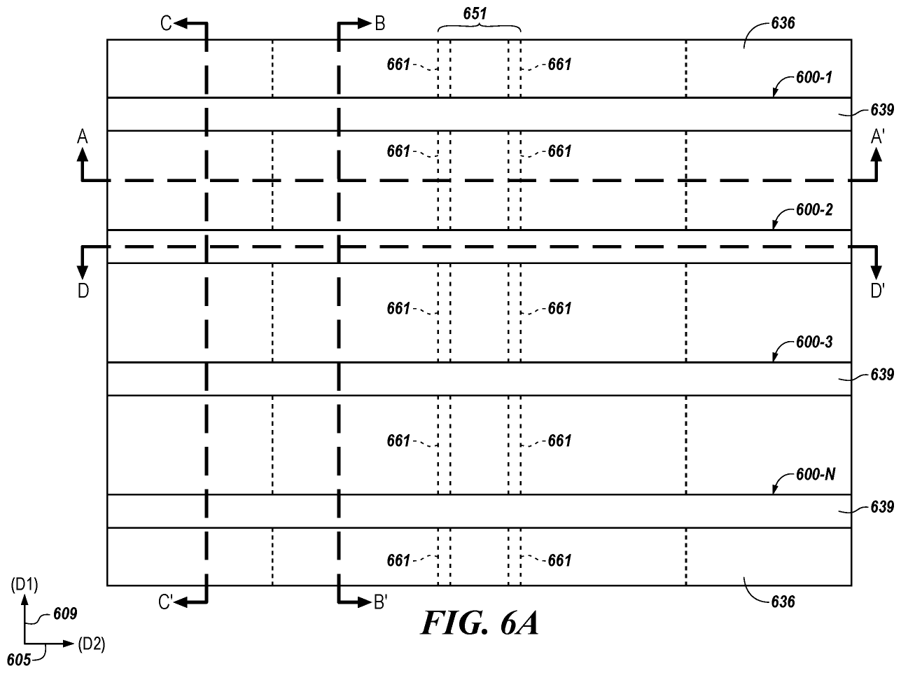

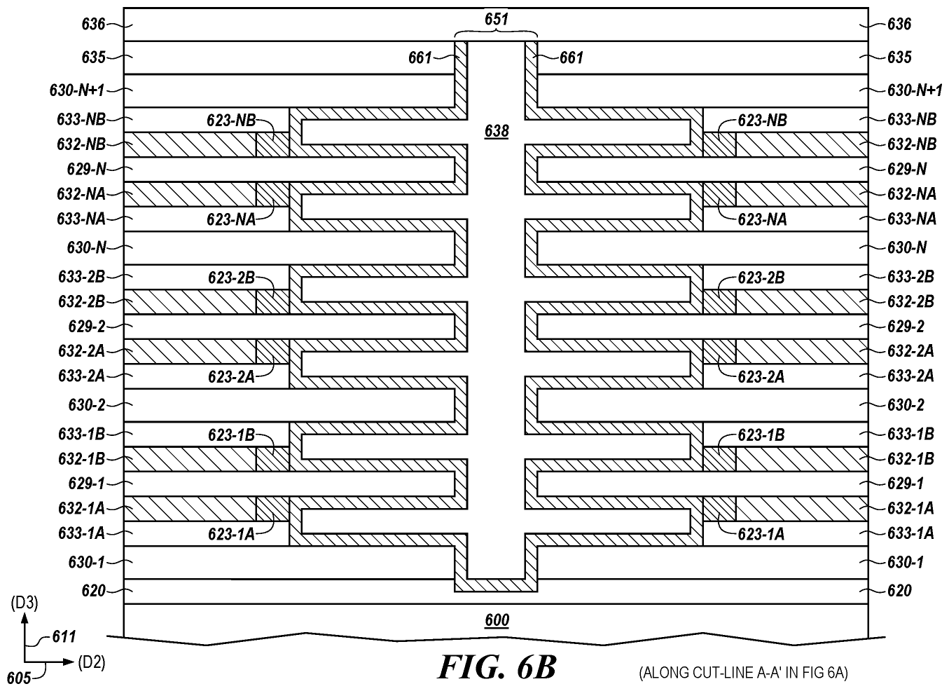

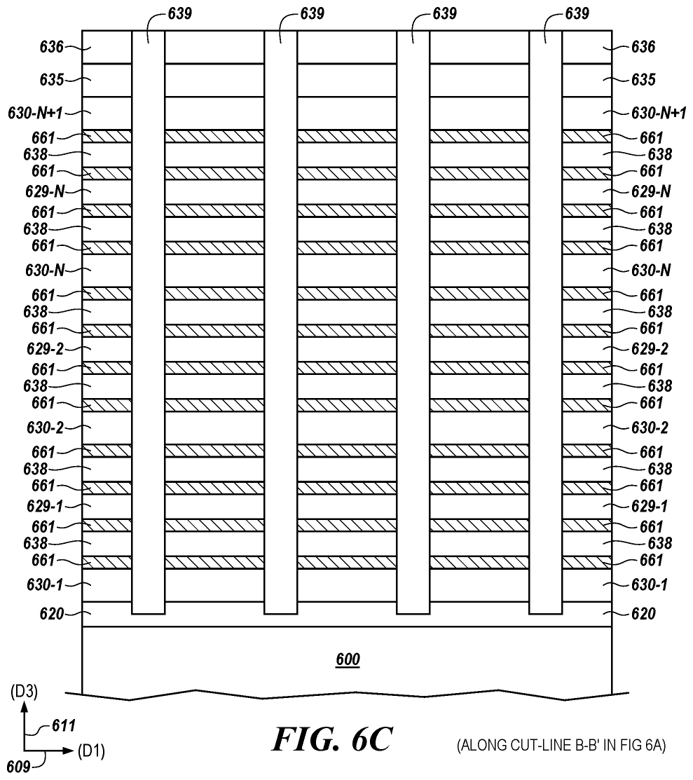

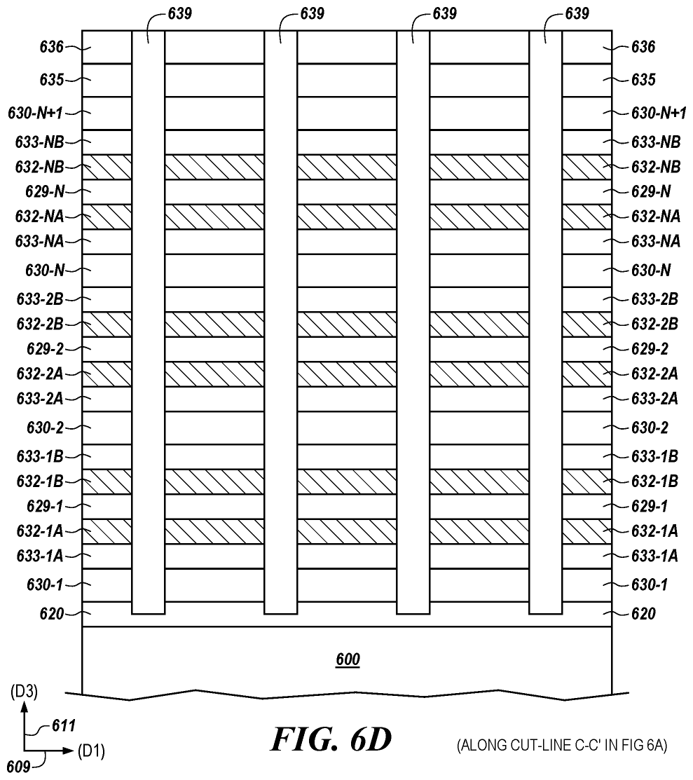

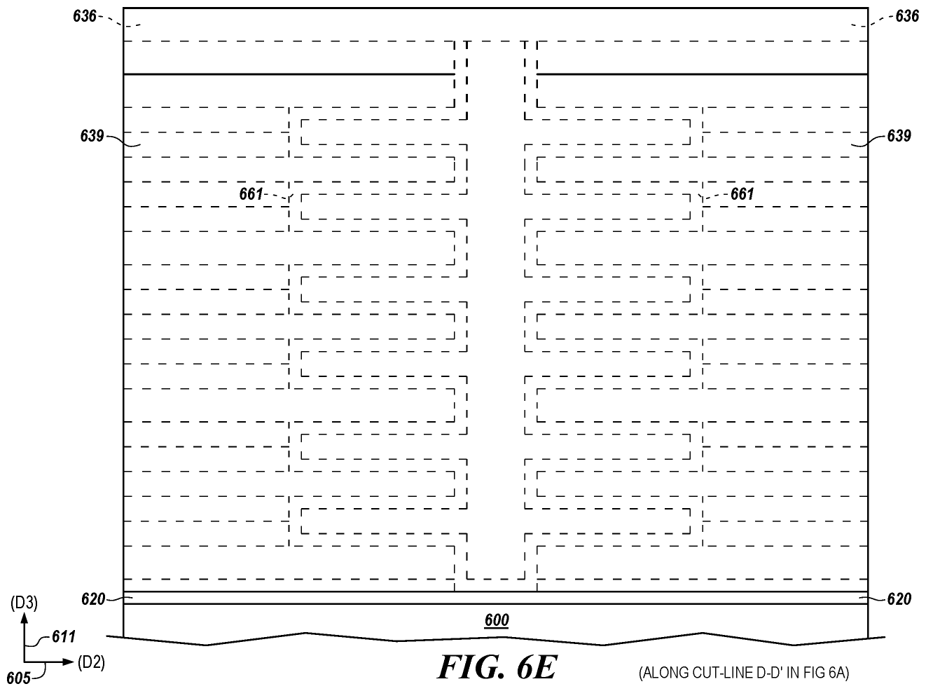

FIGS. 6A-6D illustrate an example method, at another stage of a semiconductor fabrication process, for forming arrays of vertically stacked memory cells, having a twin channel access device for vertical three-dimensional (3D) memory, such as illustrated in FIGS. 1-3, and in accordance with a number of embodiments of the present disclosure.

FIG. 6A illustrates a top down view of a semiconductor structure, at a particular point in time, in a semiconductor fabrication process, according to one or more embodiments. In the example embodiment of FIG. 6A, the method comprises using a photolithographic process to pattern the photolithographic mask 636. The method in FIG. 6A further illustrates using one or more etchant processes to form a plurality of vertical openings 600-1, 600-2, . . . , 600-N, e.g., second vertical openings, through the vertical stack (shown in FIG. 4) in a first (D1) 609 and a second (D2) 605 direction. The second vertical opening 600 is illustrated extending predominantly in the second horizontal direction (D2) 605.

As shown in FIG. 6A, the one or more etchant processes forms vertical openings 600 to fill with a sixth dielectric 639 to separate the first electrode 661 in the first horizontal direction (D1) 609 in the first horizontal openings, in the repeating iterations of alternating layers of the first dielectric material, 630-1, 630-2, . . . , 630-N, the second dielectric material, 633-1A, 633-2A, . . . , 633-NA, the first semiconductor material, 632-1A, 632-2A, 632-NA, the third dielectric material, 629-1, 629-2, . . . , 629-N, the second semiconductor material, 632-1B, 632-2B, . . . , 632-NB, and the fourth dielectric material, 633-1B, 633-2B, . . . , 633-NB, in the vertical stack ascending in the third, vertical direction (D3) 611.

FIG. 6B illustrates the structure in one example embodiment at this particular point in the semiconductor fabrication process, taken along cut-line A-A′ in FIG. 6A. FIG. 6C illustrates the structure in one example embodiment at this particular point in the semiconductor fabrication process, taken along cut-line B-B′ in FIG. 6A. FIG. 6D illustrates the structure in one example embodiment at this particular point in the semiconductor fabrication process, taken along cut-line C-C′ in FIG. 6A. FIG. 6E illustrates the structure in one example embodiment at this particular point in the semiconductor fabrication process, taken along cut-line D-D′ in FIG. 6A.

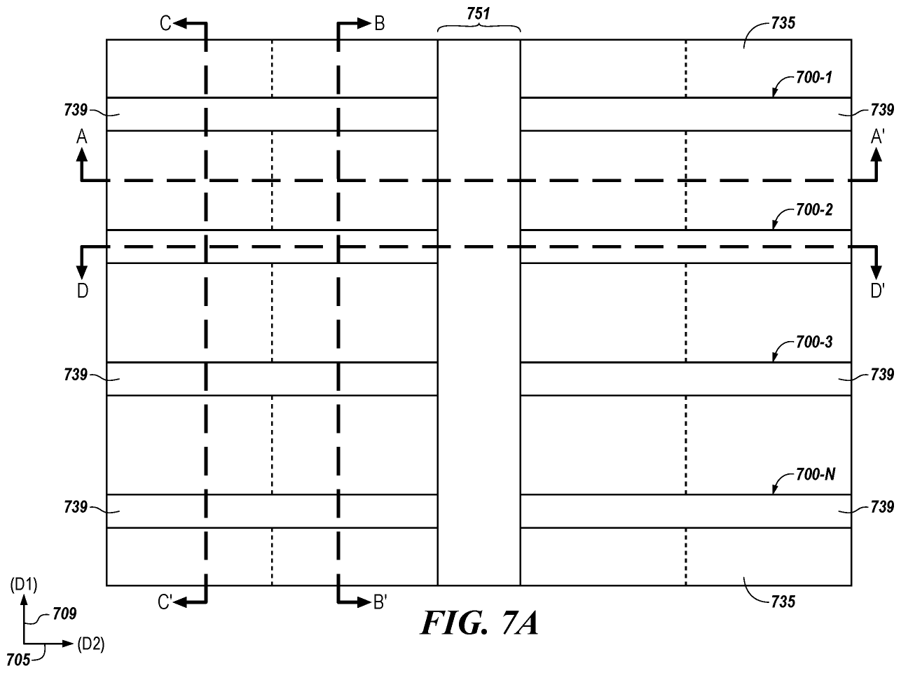

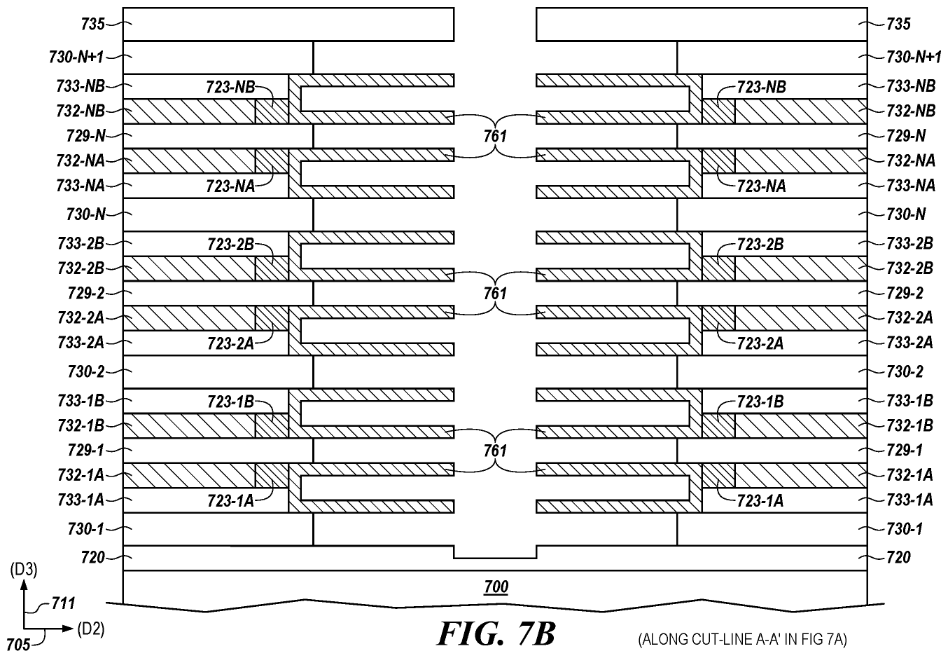

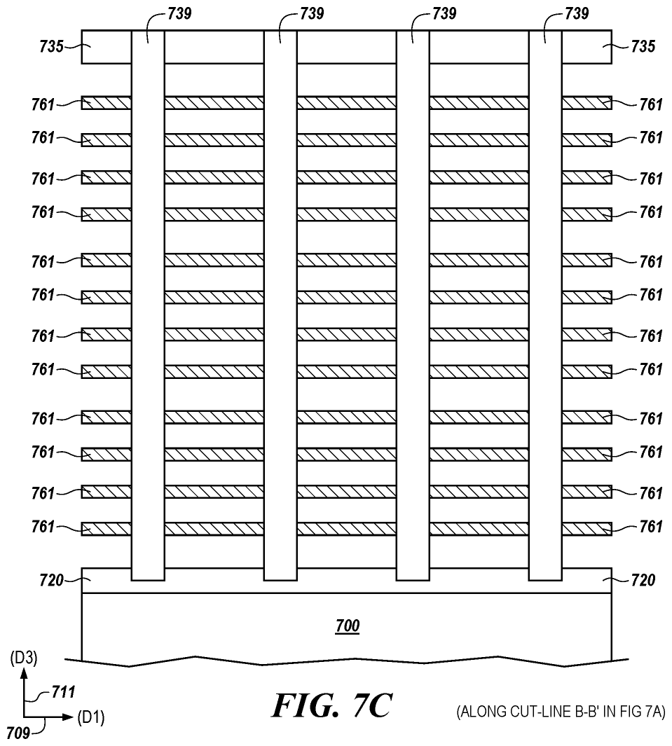

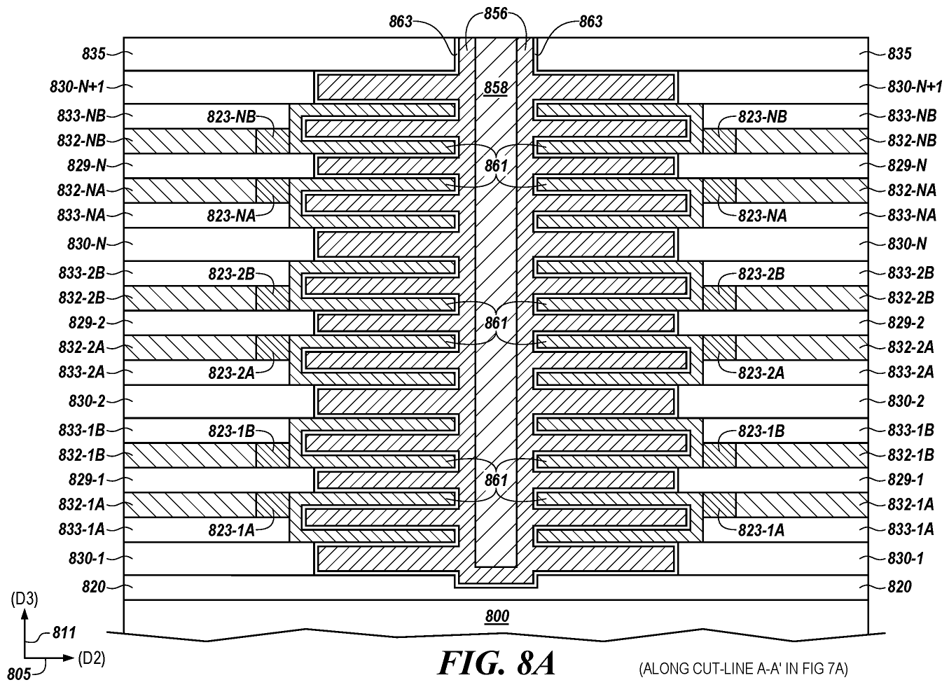

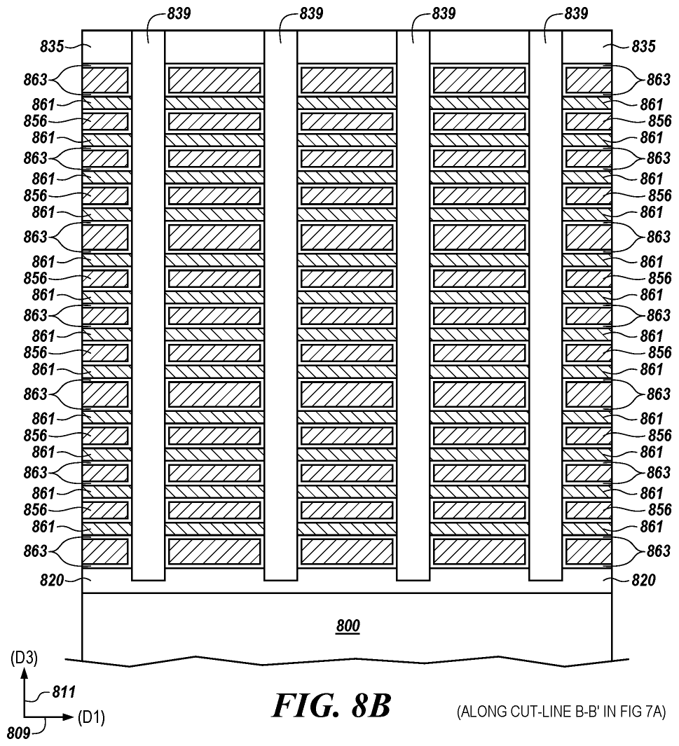

FIGS. 7A-7C illustrate an example method, at another stage of a semiconductor fabrication process, for forming arrays of vertically stacked memory cells, having a twin channel access device for vertical three-dimensional (3D) memory, such as illustrated in FIGS. 1-3, and in accordance with a number of embodiments of the present disclosure.

FIG. 7A illustrates a top down view of a semiconductor structure, at a particular point in time, in a semiconductor fabrication process, according to one or more embodiments. In the example embodiment of FIG. 7A, the method comprises using a photolithographic process to pattern the photolithographic mask 735. The method in FIG. 7A further illustrates using one or more etchant processes to selectively remove the fifth dielectric 538 (FIG. 5) from the original first vertical openings 751, extending in the first direction (D1) 1205, and the first horizontal openings (779 shown in FIG. 7B).

FIG. 7B illustrates the structure in one example embodiment at this particular point in the semiconductor fabrication process, taken along cut-line A-A′ in FIG. 7A. FIG. 7C illustrates the structure in one example embodiment at this particular point in the semiconductor fabrication process, taken along cut-line B-B′ in FIG. 7A showing the separated first electrodes 761.

As shown in FIG. 7B, taken along cut-line A-A′ in FIG. 7A, the masked, selective etch process re-opens the first vertical opening (551 in FIG. 5A) and the first horizontal openings (579 in FIG. 5B) through the repeating iterations of alternating layers of the first dielectric material, 730-1, 730-2, . . . , 730-N, the second dielectric material, 733-1A, 733-2A, . . . , 733-NA, the first semiconductor material, 732-1A, 732-2A, . . . , 732-NA, the third dielectric material, 729-1, 729-2, . . . , 729-N, the second semiconductor material, 732-1B, 732-2B, . . . , 732-NB, and the fourth dielectric material, 733-1B, 733-2B, . . . , 733-NB, in the vertical stack ascending in the third, vertical direction (D3) 711.

FIGS. 8A-8B illustrate an example method, at another stage of a semiconductor fabrication process, for forming arrays of vertically stacked memory cells, having a twin channel access device for vertical three-dimensional (3D) memory, such as illustrated in FIGS. 1-3, and in accordance with a number of embodiments of the present disclosure.

FIG. 8A illustrates a cross sectional view taken along cut-line A-A′ in FIG. 7A, at a particular point in time, in a semiconductor fabrication process, according to one or more embodiments. In the example embodiment of FIG. 8A, the method comprises depositing a second electrode 856 separated by a cell dielectric 863. FIG. 8B illustrates a cross sectional view taken along cut-line B-B′ in FIG. 7A.

In one embodiment, the cell dielectric 863 may be conformally deposited on the first electrode 861 (also referred to as a bottom electrode (BE)) in the first vertical openings, the first horizontal openings, an on other exposed surfaces. In one embodiment, the cell dielectric 863 may be a high-K dielectric, as described herein, conformally deposited to a thickness (t1) in a range of approximately 2 to 10 nanometers (nm). Embodiments, however, are not limited to this example thickness. Other suitable thicknesses may be achieved.

In one embodiment the second electrode 856 may be deposited by chemical vapor deposition (CVD), or other suitable technique, on the cell dielectric 863 in the first vertical openings, the first horizontal openings, an on other exposed surfaces, to fill the first vertical openings. In some embodiments the second electrode 856 may also be referred to as a top electrode (TE), common electrode (CE), and/or top plate electrode. Embodiments, however, are not limited to these examples. Other suitable semiconductor fabrication techniques and/or storage nodes structures, such as ferroelectric cells, may be used.

FIGS. 9A-9B illustrate an example method, at another stage of a semiconductor fabrication process, for forming arrays of vertically stacked memory cells, having a twin channel access device for vertical three-dimensional (3D) memory, such as illustrated in FIGS. 1-3, and in accordance with a number of embodiments of the present disclosure.

FIG. 9A illustrates a top down view of a semiconductor structure, at a particular point in time, in a semiconductor fabrication process, according to one or more embodiments. In the example embodiment of FIG. 9A, the method comprises using a photolithographic process to pattern the photolithographic mask 936. The method in FIG. 9A further illustrates using one or more etchant processes to form third vertical openings 970 down through the vertical stack, extending in the first direction (D1) 905.

FIG. 9B illustrates a cross sectional view taken along cut-line A-A′ in FIG. 9A. As illustrated in FIG. 9B, the etchant processes may additionally selectively remove the sixth dielectric (639 from FIGS. 6A-6D), extending in the first direction (D1) 605.

FIGS. 10A-10B illustrate the structure in one example embodiment at a next particular point in the semiconductor fabrication process. FIG. 10A is a cross sectional view taken along cut-line A-A′ in FIG. 9A. In the example embodiment of FIG. 10A, a selective etch process may be used to recess the first, the second, and the third dielectric materials, 1033-1A, 1029-1, and 1033-1B, 1033-2A, 1029-2, and 1033-2B, 1033-NA, 1029-N, and 1033-NB, horizontally to form an opening, a second distance (L2) from the third vertical opening 1070, above and below the first and the second semiconductor materials, 1032-1A and 1032-1B, 1032-2A and 1032-2B, . . . , 1032-NA and 1032NB. FIG. 10B illustrates a cross sectional view taken along cut-line C-C′ in FIG. 9A.

In the example embodiment of FIGS. 10A-10B, the method may include flowing a selective etchant into the third vertical opening 1070 to selectively etch a portion of the first and third dielectric materials 1033-A and 1033-B, and the second dielectric material 1029. For example, an etchant may be flowed into the second vertical opening 1070 to selectively etch a nitride material 1033-A and 1033-B, and to selectively etch an oxide material 1029. The etchant may target all iterations of the first and third dielectric material 1033-A and 1033-B and the second dielectric material 1029 within the stack. As such, the etchant may target a first and third nitride material 1033-A and 1003-B, and the second oxide material 1029 within the stack.

The selective etchant process may consist of one or more etch chemistries selected from an aqueous etch chemistry, a semi-aqueous etch chemistry, a vapor etch chemistry, or a plasma etch chemistries, among other possible selective etch chemistries. For example, a dry etch chemistry of oxygen (O₂) or O₂ and sulfur dioxide (SO₂) (O₂/SO₂) may be utilized. As another example, a dry etch chemistries of O₂ or of O₂ and nitrogen (N₂) (O₂/N₂) may be used to selectively etch the first and third dielectric material 1033-A and 1033-B, and second dielectric material 1029. Alternatively, or in addition, a selective etch to remove the first and third dielectric material 1033-A and 1033-B, and second dielectric material 1029 may comprise a selective etch chemistry of phosphoric acid (H₃PO₄) or hydrogen fluoride (HF) and/or dissolving the first and third dielectric material 1033-A and 1033-B, and the second dielectric material 1029 using a selective solvent, for example NH₄OH or HF, among other possible etch chemistries or solvents. Embodiments are not limited to these examples.

The selective etchant process may etch the nitride material and/or oxide material 1033 and 1029 to form second horizontal openings 1073. The selective etchant process may be performed such that the second horizontal opening 1073 has a length or depth (L2) a second distance 1076 from the second vertical opening 1070. The first and third dielectric material 1033-A and 1033-B, and second dielectric material 1029 may be etched a second distance (L2) 1076 in a range of approximately fifty (50) to one hundred and fifty (150) nanometers (nm) back from the second vertical opening 1070. The second distance (L2) 1076 may be controlled by controlling time, composition of etchant gas, and etch rate of a reactant gas flowed into the second vertical opening 1070, e.g., rate, concentration, temperature, pressure, and time parameters. The selective etch may be isotropic, but selective to the first and third dielectric material 1033-A and 1033-B, and second dielectric material 1029. In this example the second horizontal opening 1073 will have a height (H1) substantially equivalent to and be controlled by a thickness, to which the first and third dielectric layer 1033-A and 1033-B, and second dielectric material 1029, e.g., nitride and/or oxide material, were deposited. Embodiments, however, are not limited to this example.

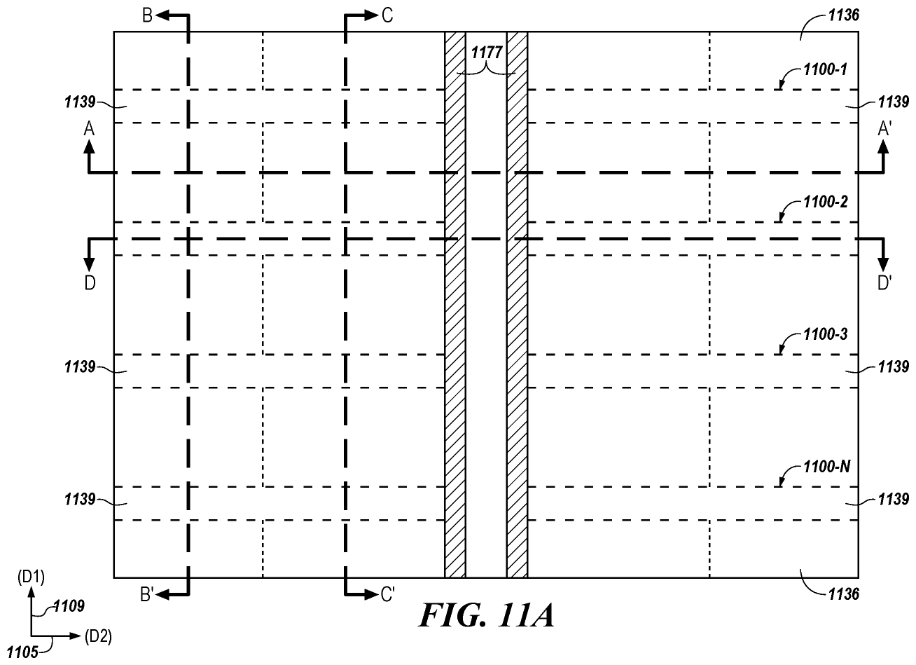

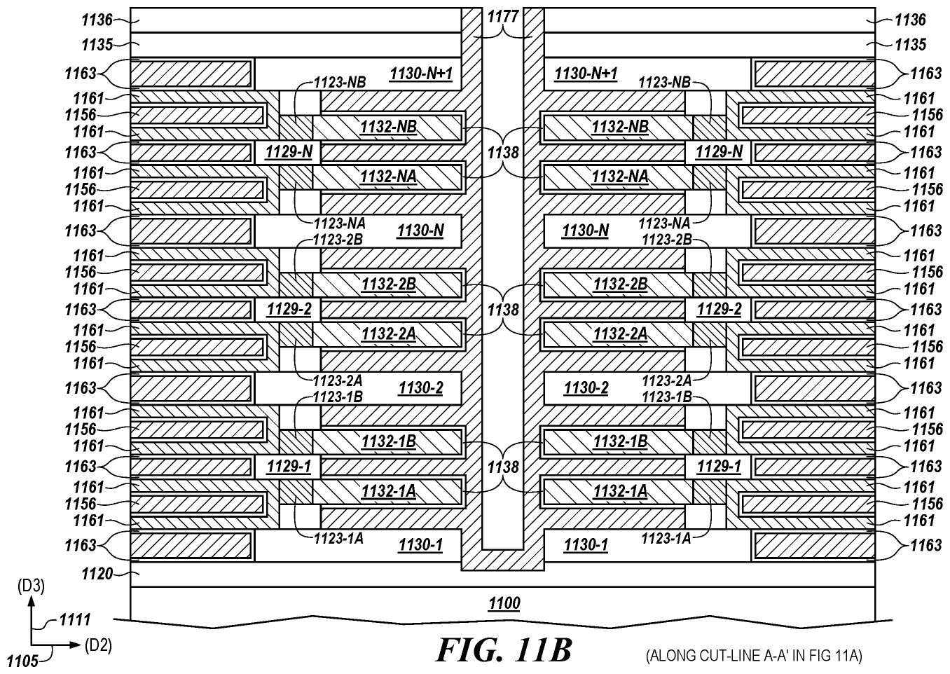

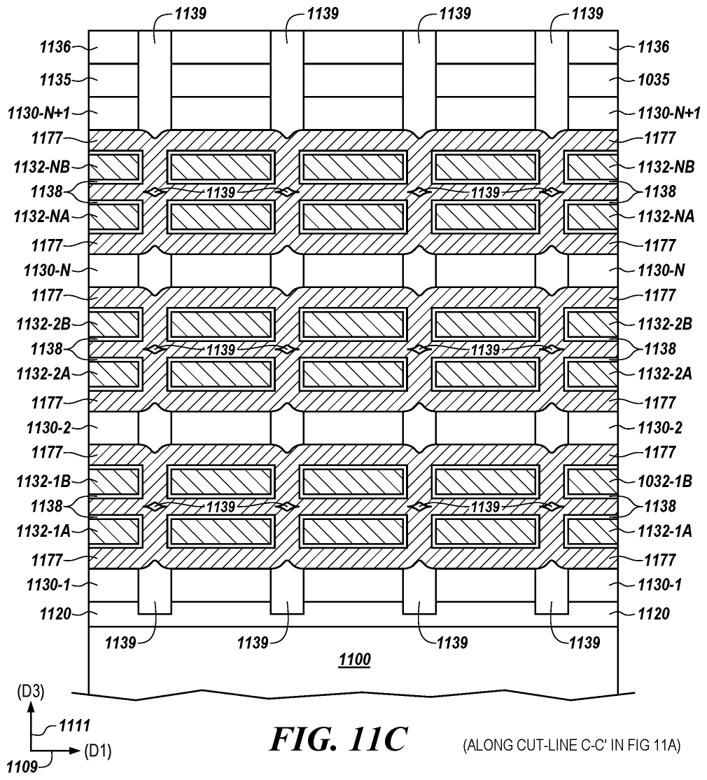

FIGS. 11A-11C illustrate an example method, at another stage of a semiconductor fabrication process, for forming arrays of vertically stacked memory cells, having a twin channel access device for vertical three-dimensional (3D) memory, such as illustrated in FIGS. 1-3, and in accordance with a number of embodiments of the present disclosure.

FIG. 11A illustrates a top-down view of a semiconductor structure, at a particular point in time, in a semiconductor fabrication process, according to one or more embodiments, for depositing a conductive gate material on a gate dielectric.

FIG. 11B illustrates a cross sectional view taken along cut-line A-A′ in FIG. 11A. In the example embodiment shown in FIG. 11B, a gate dielectric material 1138 may be deposited in the plurality of second horizontal openings 1173 created by the etched first and third, and second dielectric materials 1133-A, 1133-B, and 1129. The gate dielectric material 1138 may be conformally deposited all around the first and the second semiconductor materials, 1132-1A and 1132-1B, 1132-2A and 1132-2B, . . . , 1132-NA and 1132NB. A gate dielectric material 1138 may be conformally deposited in the plurality of second horizontal openings 1173 using a chemical vapor deposition (CVD) process, plasma enhanced CVD (PECVD), atomic layer deposition (ALD), or other suitable deposition process, to cover the first and the second semiconductor materials, 1132-1A and 1132-1B, 1132-2A and 1132-2B, . . . , 1132-NA and 1132NB. By way of example, and not by way of limitation, the gate dielectric 1138 may comprise a silicon dioxide (SiO₂) material, aluminum oxide (Al₂O₃) material, high dielectric constant (k), e.g., high-k, dielectric material, and/or combinations thereof.

As shown in the example embodiment of FIG. 11B, a first conductive material, 1177-1, 1177-2, . . . , 1177-N (collectively referred to as first conductive material 1177), may be deposited on the gate dielectric material 1138 all around the first and the second semiconductor materials, 1132-1A and 1132-1B, 1132-2A and 1132-2B, . . . , 1132-NA and 1132NB. The first conductive material 1177 may be deposited fully around every surface of the semiconductor material, to form gate all around (GAA) gate structures, at the channel region of the first and the second semiconductor material, 1132-1A and 1132-1B, 1132-2A and 1132-2B, . . . , 1132-NA and 1132NB.

The first conductive material 1177 may be conformally deposited into a portion of the second vertical opening 1170, using a chemical vapor deposition (CVD) process, plasma enhanced CVD (PECVD), atomic layer deposition (ALD), or other suitable deposition process, such that the first conductive material 1177 is fully deposited into the second horizontal opening 1173.

In some embodiments, the first conductive material, 1177 may comprise one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc, and/or some other combination thereof as also described in FIG. 3. The first conductive material 1177 with the gate dielectric material 1138 may form horizontally oriented access lines opposing a channel region of the semiconductor material, such as shown as access lines 103-1, 103-2, . . . , 103-Q in FIGS. 1-3 (which also may be referred to a wordlines). FIG. 11C illustrates a cross sectional view taken along cut-line B-B′ in FIG. 11A.

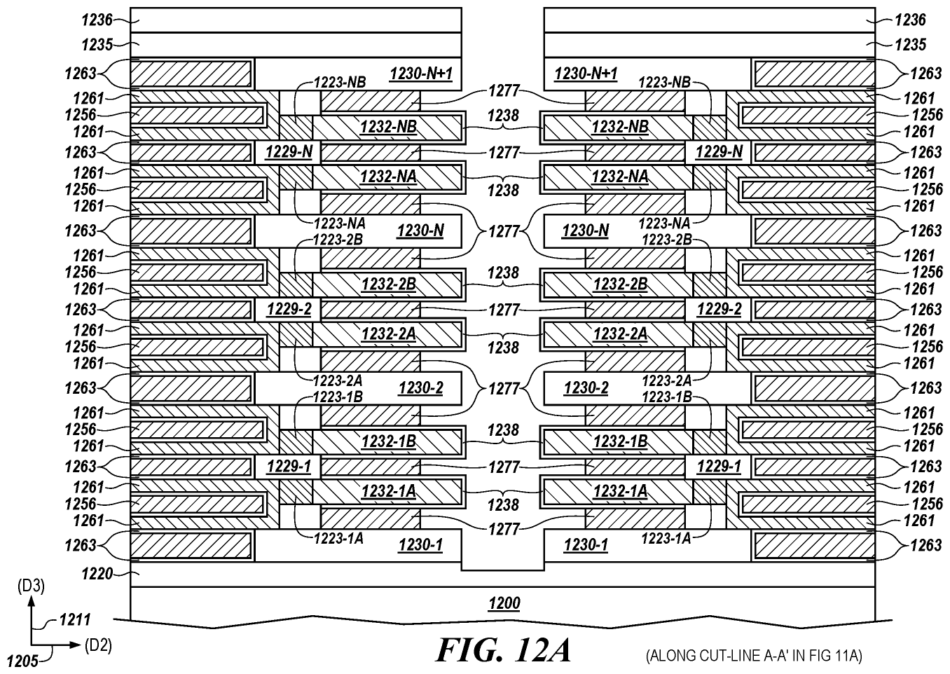

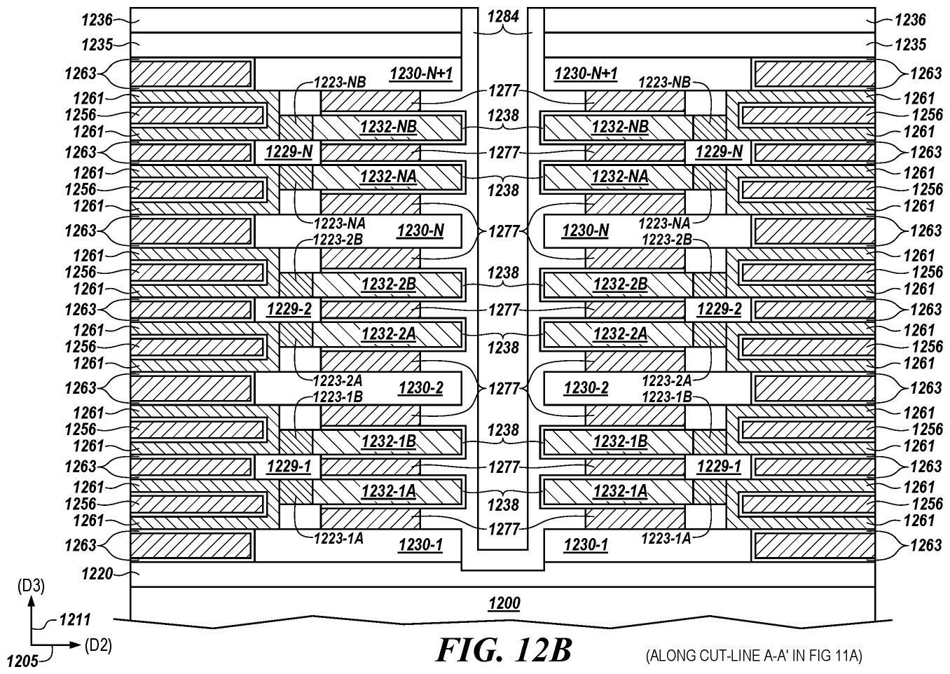

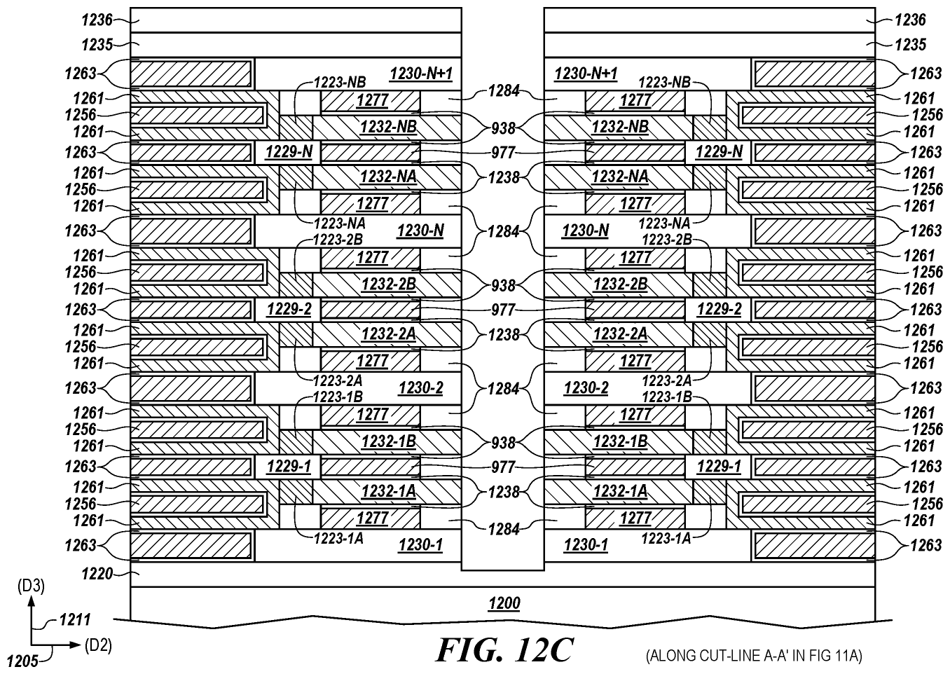

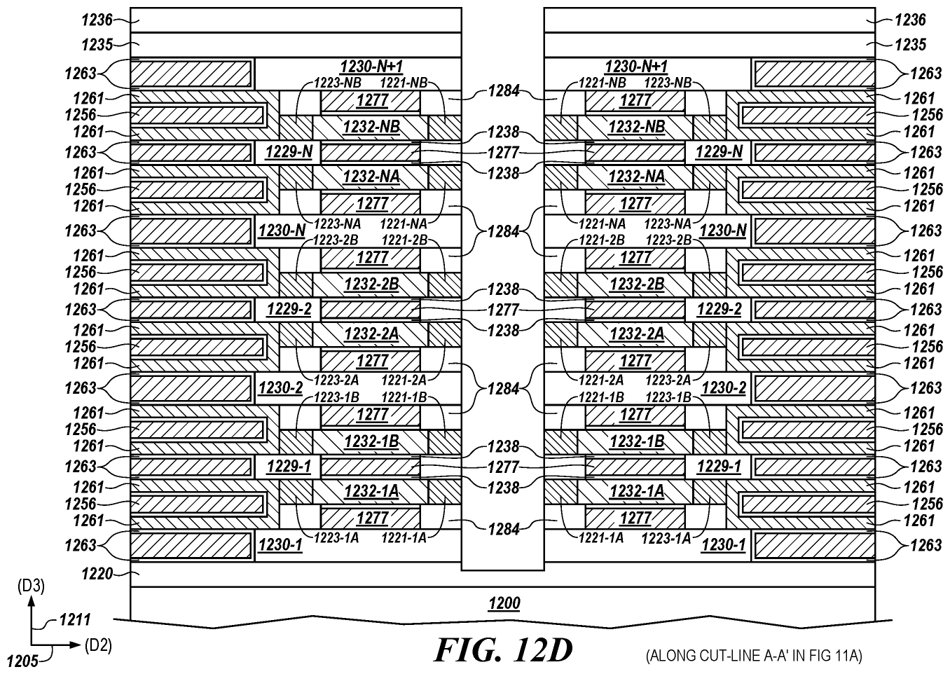

FIGS. 12A-12D illustrates an example method, at another stage of a semiconductor fabrication process, for forming arrays of vertically stacked memory cells, having a twin channel access device for vertical three-dimensional (3D) memory, such as illustrated in FIGS. 1-3, and in accordance with a number of embodiments of the present disclosure.

FIG. 12A illustrates a cross sectional view taken along cut-line A-A′ in FIG. 11A. The cross-sectional view shown in FIG. 12A illustrates that the first conductive material 1277 may be recessed back in the second horizontal opening 1273, e.g., etched away from the third vertical opening 1270 using an atomic layer etching (ALE) or other suitable technique. In some examples, the first conductive material 1277 may be etched back in the horizontal openings 1273 a third distance (L3) 1283 into the continuous second horizontal openings 1273. In some embodiments, the first conductive material 1277 may be etched back in the horizontal opening 1273 a third distance (L3) 1283 in a range of twenty (20) to fifty (50) nanometers (nm) back from the third vertical opening 1270. The first conductive material 1277 may be selectively etched, leaving the gate dielectric material 1238 intact.

FIG. 12B illustrates an example embodiment of the structure at another point in time in the semiconductor fabrication process. FIG. 12B is a cross sectional view taken along cut-line A-A′ in FIG. 11A. As shown in the embodiment of FIG. 12B, another dielectric material 1284 may be deposited to fill the second horizontal openings 1273 from the recessed first conductive material 1277, and to fill, at least conformally on the vertical sidewalls, the third vertical opening 1270.

In some embodiments the “another dielectric material”, e.g., 1284, may be the same material or a different material as the first and the second, and the third dielectric materials, 1233 and 1229. For example, the dielectric material may be Si₃N₄. In another example, the dielectric materials may comprise a silicon dioxide (SiO₂) material. In another example, the dielectric materials may comprise a silicon oxy-carbide (SiOₓC_{y}) material. In another example, the dielectric materials may include silicon oxy-nitride (SiOₓN_{y}), and/or combinations thereof. Embodiments are not limited to these examples.

FIG. 12C is a cross sectional view taken along cut-line A-A′ in FIG. 11A. FIG. 12C illustrates that the dielectric 1284 may be etched to remove from the vertical sidewalls of the third vertical opening 1270. A selective etch may also be performed to remove the gate dielectric from the vertical sidewalls of the third vertical opening 1270.

FIG. 12D is also a cross sectional view taken along cut-line A-A′ in FIG. 11A at another stage of a semiconductor fabrication process, for forming arrays of vertically stacked memory cells, having a twin channel access device for vertical three-dimensional (3D) memory. As shown in the example embodiment of FIG. 12D a gas phase doping process may then be used to form first source/drain regions, 1221-1A and 1221-1B, 1221-2A and 1221-2B, . . . , 1221-NA and 1221-NB, in exposed vertical surfaces of the first and the second semiconductor material, 1232-1A and 1232-1B, 1232-2A and 1232-2B, . . . , 1232-NA and 1232NB. The third vertical opening may then be refilled with another dielectric, e.g., 1284, as described above.

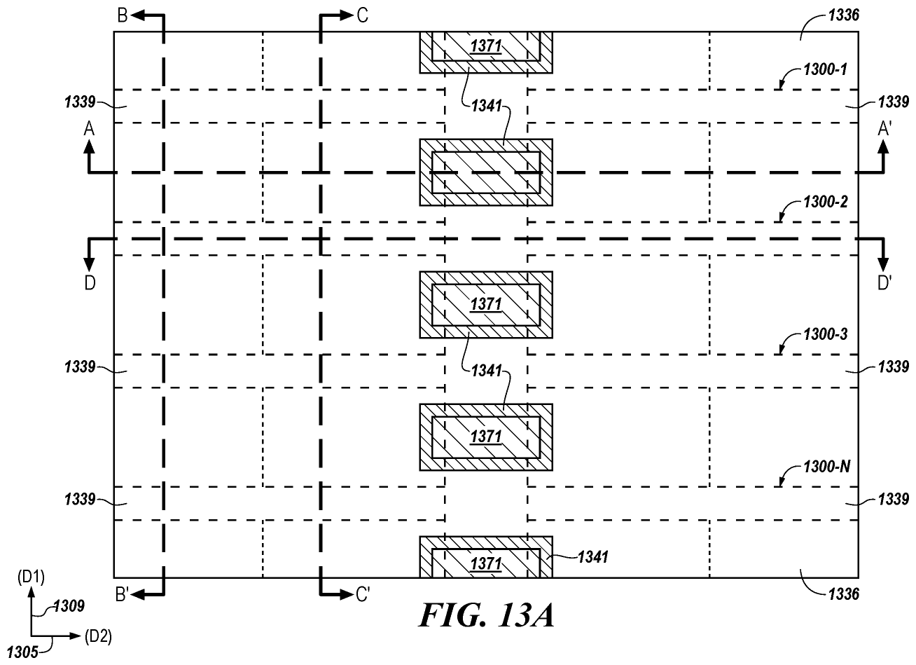

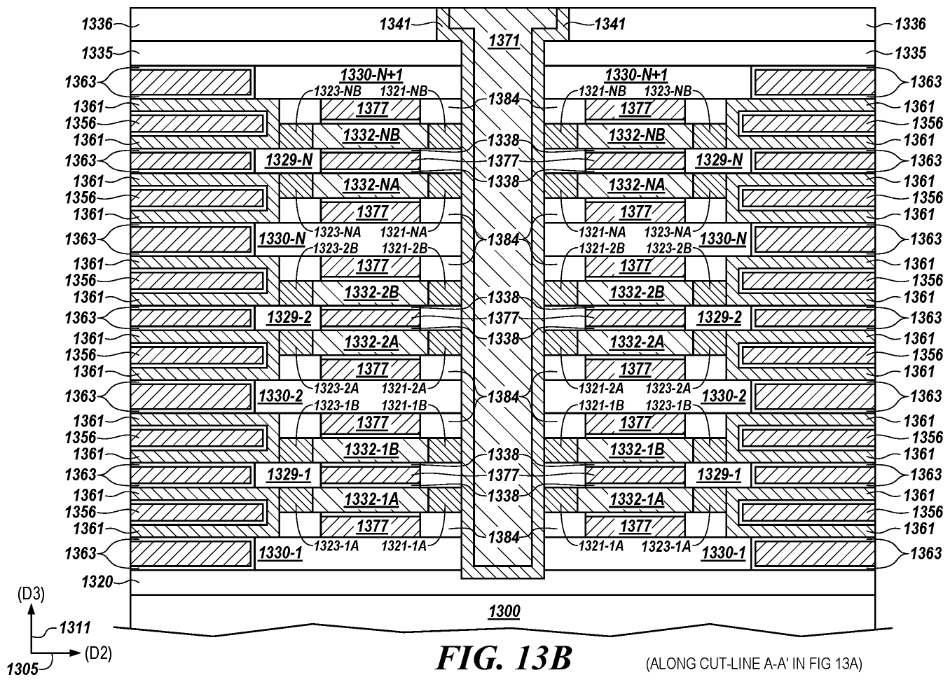

FIGS. 13A-13-B illustrate several views of an example method, at another stage of a semiconductor fabrication process, for forming arrays of vertically stacked memory cells, having a twin channel access device for vertical three-dimensional (3D) memory, such as illustrated in FIGS. 1-3, and in accordance with a number of embodiments of the present disclosure.

FIG. 13A illustrates a top down view of a semiconductor structure, at a particular point in time, in a semiconductor fabrication process, according to one or more embodiments. In the example embodiment of FIG. 13A, the method comprises using a photolithographic process to pattern a photolithographic mask 1336 to form a plurality of patterned third vertical openings through the vertical stack adjacent the first source/drain regions 1321 in which to deposit a second conductive material 1341 for forming vertically oriented digit lines 1341 and 1371.

FIG. 13B illustrates a cross sectional view taken along cut-line A-A′ in FIG. 13A. As illustrated in in FIG. 13B, the method further illustrates using one or more etchant processes to form the plurality of patterned third vertical openings through the vertical stack adjacent first source/drain regions, 1321-1A and 1321-1B, 1321-2A and 1321-2B, . . . , 1321-NA and 1321-NB. As illustrated in FIG. 13B, in some example embodiments, a highly doped semiconductor material as the second conductive material 1341 may be formed vertically in the third vertical openings 1370. The second conductive material 1341 may be in direct electrical contact with the first source/drain regions, 1321-1A and 1321-1B, 1321-2A and 1321-2B, . . . , 1321-NA and 1321-NB. The second conductive material 1341 may be a high concentration, n-type dopant polysilicon material. For example, the high concentration, n-type dopant may be formed by depositing a highly phosphorus (P) doped (n+ type) polysilicon germanium (SiGe) material as the second conductive material 1341.

In some embodiments the first source/drain regions, 1321-1A and 1321-1B, 1321-2A and 1321-2B, . . . , 1321-NA and 1321-NB, may be formed by out-diffusing n-type (n+) dopants into the first and the second semiconductor material, 1332-1A and 1332-1B, 1332-2A and 1332-2B, . . . , 1332-NA and 1332NB. For example, the plurality of patterned third vertical openings may be adjacent the first source/drain regions, 1321-1A and 1321-1B, 1321-2A and 1321-2B, . . . , 1321-NA and 1321-NB, and the high concentration, n-type dopant may be out-diffused into the low doped first and second semiconductor material, 1332-1A and 1332-1B, 1332-2A and 1332-2B, . . . , 1332-NA and 1332NB, using an annealing process to form the first source/drain regions, 1321-1A and 1321-1B, 1321-2A and 1321-2B, . . . , 1321-NA and 1321-NB.

In some embodiments, the second conductive material 1341 may comprise a titanium/titanium nitride (TiN) second conductive material 1341. The TiN second conductive material 1341 may be annealed to form a titanium silicide with the first source/drain regions, 1321-1A and 1321-1B, 1321-2A and 1321-2B, . . . , 1321-NA and 1321-NB, of the twin channel access device for vertical three-dimensional (3D) memory.

As shown in the example embodiment of FIG. 13B, the method may additionally include depositing a third conductive material 1371, e.g., a metal layer, on the titanium/titanium nitride (TiN) second conductive material 1341, which forms the titanium silicide with the first source/drain regions, 1321-1A and 1321-1B, 1321-2A and 1321-2B, . . . , 1321-NA and 1321-NB, in the plurality of patterned third vertical openings 1370 to fill and form bi-layer, vertically oriented digit lines 1341 and 1371. In some embodiments the depositing a metal layer 1371 may include depositing a cobalt (Co) material layer 1371 on the titanium/titanium nitride (TiN) second conductive material 1341 which forms the titanium silicide with the first source/drain regions, 1321-1A and 1321-1B, 1321-2A and 1321-2B, . . . , 1321-NA and 1321-NB, of the twin channel access device for vertical three-dimensional (3D) memory.

In some embodiments, depositing a metal layer 1371 on the second conductive material 1341 may comprise depositing a Ruthenium (Ru) material 1371. In some embodiments, depositing a metal layer 1371 on the second conductive material 1341 may comprised depositing a tungsten (W) material 1371. Depositing the metal layer 1371 may include chemical vapor deposition, or other suitable deposition technique. Embodiments, however, are not limited to these examples.

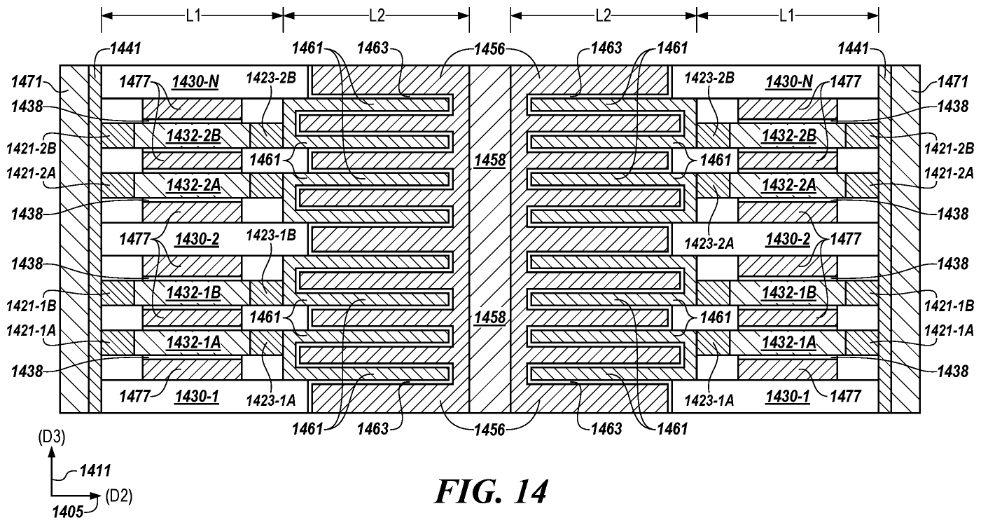

FIG. 14 illustrates another cross sectional view taken along cut-line A-A′ in FIG. 13A showing completed twin channel access devices for vertical three-dimensional (3D) memory having horizontally oriented access devices and horizontally oriented storage nodes. As shown in the example embodiment of FIG. 14 the twin channel access devices for vertical three-dimensional (3D) includes horizontally oriented access lines 1477 and vertically oriented digit lines 1441 and 1471.

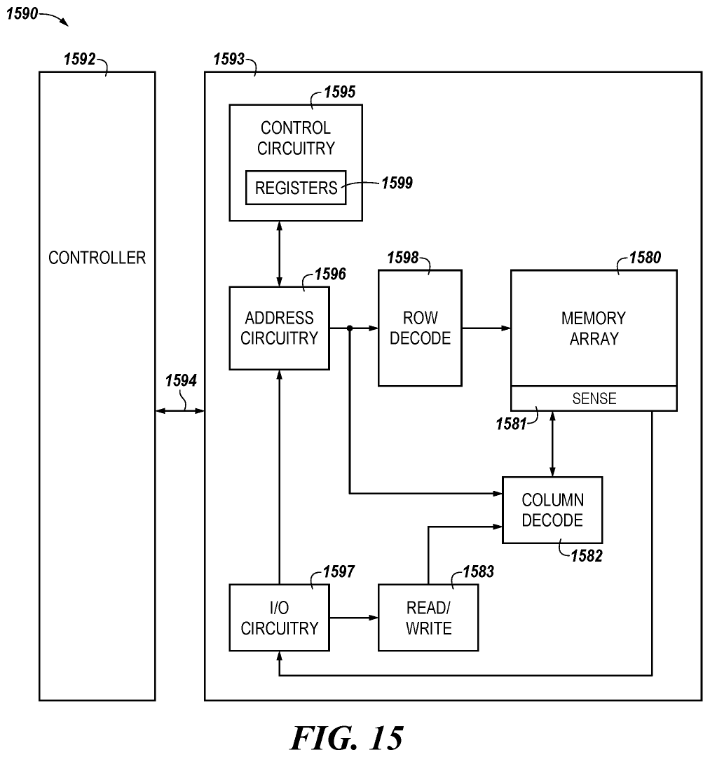

FIG. 15 is a block diagram of an apparatus in accordance with a number of embodiments of the present disclosure. FIG. 15 is a block diagram of an apparatus in the form of a computing system 1507 including a memory device 1508 in accordance with a number of embodiments of the present disclosure. As used herein, a memory device 1508, a memory array 1510, and/or a host 1501, for example, might also be separately considered an “apparatus.” According to embodiments, the memory device 1501 may comprise at least one memory array 1510 with a memory cell formed having a twin channel access device for vertical three-dimensional (3D) that includes horizontally oriented access devices coupled to horizontally oriented storage nodes and includes horizontally oriented access lines and vertically oriented digit lines.

In this example, system 1507 includes a host 1501 coupled to memory device 1508 via an interface 1513. The computing system 1507 can be a personal laptop computer, a desktop computer, a digital camera, a mobile telephone, a memory card reader, or an Internet-of-Things (IOT) enabled device, among various other types of systems. Host 1501 can include a number of processing resources, e.g., one or more processors, microprocessors, or some other type of controlling circuitry, capable of accessing memory 1508. The system 1507 can include separate integrated circuits, or both the host 1501 and the memory device 1508 can be on the same integrated circuit. For example, the host 1501 may be a system controller of a memory system comprising multiple memory devices 1508, with the system controller 1509 providing access to the respective memory devices 1508 by another processing resource such as a central processing unit (CPU).

In the example shown in FIG. 8, the host 1501 is responsible for executing an operating system (OS) and/or various applications, e.g., processes, that can be loaded thereto, e.g., from memory device 1508 via controller 1509. The OS and/or various applications can be loaded from the memory device 1508 by providing access commands from the host 1501 to the memory device 1508 to access the data comprising the OS and/or the various applications. The host 1501 can also access data utilized by the OS and/or various applications by providing access commands to the memory device 1508 to retrieve said data utilized in the execution of the OS and/or the various applications.

For clarity, the system 1507 has been simplified to focus on features with particular relevance to the present disclosure. The memory array 1510 can be a DRAM array comprising at least one memory cell having a digit line and body contact formed according to the techniques described herein. For example, the memory array 1510 can be an unshielded DL 4F2 array such as a 3D-DRAM memory array. The array 1510 can comprise memory cells arranged in rows coupled by word lines, which may be referred to herein as access lines or select lines, and columns coupled by digit lines, which may be referred to herein as sense lines or data lines. Although a single array 1510 is shown in FIG. 8, embodiments are not so limited. For instance, memory device 1508 may include a number of arrays 1510, e.g., a number of banks of DRAM cells.

The memory device 1501 includes address circuitry 1503 to latch address signals provided over an interface 1513. The interface can include, for example, a physical interface employing a suitable protocol, e.g., a data bus, an address bus, and a command bus, or a combined data/address/command bus. Such protocol may be custom or proprietary, or the interface 1513 may employ a standardized protocol, such as Peripheral Component Interconnect Express (PCIe), Gen-Z, CCIX, or the like. Address signals are received and decoded by a row decoder 1506 and a column decoder 1504 to access the memory array 1510. Data can be read from memory array 1510 by sensing voltage and/or current changes on the sense lines using sensing circuitry 1511. The sensing circuitry 1511 can comprise, for example, sense amplifiers that can read and latch a page, e.g., row, of data from the memory array 1510. The I/O circuitry 1512 can be used for bi-directional data communication with the host 1501 over the interface 1513. The read/write circuitry 1505 is used to write data to the memory array 1510 or read data from the memory array 1510. As an example, the circuitry 1505 can comprise various drivers, latch circuitry, etc.

Control circuitry 1509 decodes signals provided by the host 1501. The signals can be commands provided by the host 1501. These signals can include chip enable signals, write enable signals, and address latch signals that are used to control operations performed on the memory array 1510, including data read operations, data write operations, and data erase operations. In various embodiments, the control circuitry 1509 is responsible for executing instructions from the host 1501. The control circuitry 1509 can comprise a state machine, a sequencer, and/or some other type of control circuitry, which may be implemented in the form of hardware, firmware, or software, or any combination of the three. In some examples, the host 1501 can be a controller external to the memory device 1508. For example, the host 1501 can be a memory controller which is coupled to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements, e.g., by direct physical contact, indirectly coupled and/or connected with intervening elements, or wirelessly coupled. The term coupled may further include two or more elements that co-operate or interact with each other, e.g., as in a cause and effect relationship. An element coupled between two elements can be between the two elements and coupled to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” an other element, the particular element can cover the other element, can be over the other element or lateral to the other element and/or can be in direct physical contact the other element. Lateral to may refer to the horizontal direction, e.g., the y-direction or the x-direction, that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. A memory device, comprising:
a twin channel, horizontally oriented access device having;
a first source/drain region and a second source/drain region separated by a first channel region, being operatively controlled by a first gate separated from the first channel region by a first gate dielectric; and
a third source/drain region and a fourth source/drain region separated by a second channel region, being operatively controlled by a second gate separated from the second channel region by a second gate dielectric;
a first horizontally oriented storage node coupled to the second source/drain region of the twin channel access device; and
a second horizontally oriented storage node coupled to the fourth source/drain region of the twin channel access device.

2. The memory device of claim 1, wherein the first and the second gates are electrically connected.

3. The memory device of claim 1, wherein the first and the second gates are horizontally oriented gates.

4. The memory device of claim 3, wherein the first source/drain region of the twin channel access device and the third source/drain region of the twin channel access device are coupled to a vertically oriented digit line.

5. The memory device of claim 1, wherein the first gate is a horizontally oriented dual gate structure having a top gate portion vertically above the first channel region and a bottom gate portion vertically below the first channel region.

6. The memory device of claim 5, wherein the second gate is a horizontally oriented dual gate structure having a top gate portion vertically above the second channel region and a bottom gate portion vertically below the second channel region.

7. The memory device of claim 6, wherein the bottom gate portion of the first gate and the top gate portion of the second gate are a shared gate portion between the first channel region and the second channel region.

8. The memory device of claim 1, wherein:
the first and the second channel regions have a first horizontal length;
the first and the second horizontal storage nodes have a second horizontal length; and
wherein the second horizontal length is at least twenty five percent (25%) shorter than a storage node length used to maintain an equal storage capacitance value relative to a same horizontal memory device layout architecture having only a single channel horizontal access device, using a same set of operating parameters.

9. The memory device of claim 1, wherein:
the first and the second channel regions having a cumulative channel width doubling a current on (“Ion”) value relative to a same horizontal memory device layout architecture having only a single channel horizontal access device, using a same set of operating parameters.

10. The memory device of claim 1, wherein a power supply operating voltage (“Vccp”) for the memory device is less than 2.0 volts.

11. The memory device of claim 1, wherein the memory device comprises a vertically oriented three-dimensional (3D), multi-tiered memory array with each tier having twin channel, horizontally oriented access devices and first and second horizontally oriented storage nodes.

12. A memory device, comprising:
a horizontally oriented access device having a vertically stacked structure, comprising:
first horizontal gate portion;
first horizontal channel horizontally separating a first source/drain region and a second source/drain region, and separated from the first horizontal gate by a dielectric material;
a second horizontal gate portion separated from the first horizontal channel by the dielectric material;
a second horizontal channel horizontally separating a third source/drain region and a fourth source/drain region, and separated from the second horizontal gate by the dielectric material; and
a third horizontal gate portion separated from the second horizontal channel by the dielectric;
a first horizontally oriented storage node coupled to the second source/drain region; and
a second horizontally oriented storage node coupled to the fourth source/drain region.

13. The memory device of claim 12, wherein the first, second, and third horizontal gate portions are electrically coupled together to form gate on two side (G2S) structures on opposing sides, respectively, of the first and the second horizontal channel regions.

14. The memory device of claim 13, wherein the second horizontal gate has a vertical height (h2) which is less than a vertically height (h1) of the first horizontal gate and is less than a vertical height (h3) of the third horizontal gate.

15. The memory device of claim 13, wherein when actuated the second horizontal gate inverts a conductive path in both opposing sides of the first and the second horizontal channel regions to double a width of the conductive path in the first and the second horizontal channel regions.

16. The memory device of claim 12, wherein the horizontally oriented access device is a thin film transistor (TFT) and the first and the second horizontally oriented storage nodes are horizontally oriented capacitors located in a same horizontal tier to form a twin transistor, twin capacitor (2T2C) memory cell.

17. The memory device of claim 16, wherein the memory device comprises a vertically oriented three-dimensional (3D), multi-tiered memory array with each tier having twin transistor, twin capacitor (2T2C) memory cells.

18. The memory device of claim 12, wherein the first source/drain region of the first horizontal channel and the third source/drain region of the second horizontal channel are electrically coupled to a vertically oriented digit line.

19. The memory device of claim 18, wherein:
the second source/drain region of the first horizontal channel is coupled to a bottom electrode of the first horizontally oriented storage node; and
the fourth source/drain region of the second horizontal channel is coupled to a bottom electrode of the second horizontally oriented storage node.

20. The memory device of claim 12, wherein the first and the second horizontally oriented storage nodes are horizontally oriented, ferroelectric storage nodes.

21. The memory device of claim 12, wherein the first and second horizontal gates are electrically coupled together and form gate all around (GAA) structures opposing the first and the second horizontal channels.

22. The memory device of claim 21, wherein when actuated the GAA structures invert a conductive path in opposing sides of the first and the second horizontal channels to double a width of the conductive path in the first and the second horizontal channels together with the first and the third horizontal gates.

23. The memory device of claim 12, wherein the first and the second horizontally oriented storage nodes each have a horizontal length of less than two hundred (200) nanometers (nm).

24. A method of forming multi-tier, vertical three-dimensional (3D) memory, comprising:
forming a horizontally oriented access device, in a first horizontal tier of the multi-tier, vertical 3D memory, the access device having a vertically stacked;
first horizontal gate;
first horizontal channel horizontally separating a first source/drain region and a second source/drain region, and separated from the first horizontal gate by a first gate dielectric;
a second horizontal gate separated from the first horizontal channel by a second gate dielectric;
a second horizontal channel horizontally separating a third source/drain region and a fourth source/drain region, and separated from the second horizontal gate by a third gate dielectric; and
a third horizontal gate separated from the second horizontal channel by a fourth gate dielectric;
forming a first horizontally oriented storage node coupled to the second source/drain region of the first horizontal channel; and
forming a second horizontally oriented storage node coupled to the fourth source/drain region of the second horizontal channel.

25. The method of claim 24, the method further comprising forming a vertical digit line coupled to the first source/drain region of the first horizontal channel and coupled to the third source/drain region of the second horizontal channel.

26. The method of claim 24, the method further comprising coupling the first, second, and third horizontal gate together.

27. The method of claim 24, the method further comprising forming the vertically stacked horizontally oriented access device to have a total vertical height (ht) of less than one hundred and fifty (150) nanometers (nm).

28. The method of claim 24, the method further comprising forming the second horizontal gate to have a vertical height (h2) of less than ten (10) nanometers (nm).

29. The method of claim 24, the method further comprising forming the first and the second horizontal channels to each individually have a vertical height (hc1/hc2) of less than fifteen (15) nanometers (nm).

30. The method of claim 24, the method further comprising forming the first and the second horizontally oriented storage nodes to each have a horizontal length of less than three hundred (300) nanometers (nm).
